(19) United States
(12) Patent Application Publication
(10) Pub. No.: US 2017/0261465 A1
(43) Pub. Date: Sep. 14, 2017

(54) DYADIC SENSOR AND PROCESS FOR SENSING AN ANALYTE

(71) Applicant: Government of the United States of America, as represented by the Secretary of Commerce, GAITHERSBURG, MD (US)

(72) Inventors: ARVIND BALIJEPALLI, IV, WASHINGTON, DC (US); JOHN S. SUEHLE, WESTMINSTER, MD (US)

(21) Appl. No.: 15/452,810

(22) Filed: Mar. 8, 2017

Related U.S. Application Data
(60) Provisional application No. 62/307,406, filed on Mar. 11, 2016.

(51) Int. Cl. G01N 27/414; B01L 3/00; H01L 29/16; H01L 29/24; H01L 29/10

(52) U.S. Cl. CPC G01N 27/4148; H01L 29/24; H01L 29/1029; H01L 29/16; B01L 3/502715; B01L 2300/041; B01L 2200/0636; B01L 2200/12; B01L 2300/0645; B01L 2300/0887

(57) ABSTRACT

A dyadic sensor includes: an analyte gate; a transition metal dichalcogenide layer disposed on the analyte gate and including a transition metal dichalcogenide; a source electrode disposed on the two-dimensional active layer and in electrical communication with the two-dimensional active layer; a drain electrode disposed on the two-dimensional active layer and in electrical communication with the two-dimensional active layer and in electrical communication with the source electrode via the two-dimensional active layer; and a control gate disposed on the two-dimensional active layer and controlling the communication of electrical current in the two-dimensional active layer between the source electrode and the drain electrode, wherein the electrical current communicated in the two-dimensional active layer is changed in response to a change in an electrical charge present at the analyte gate due to the analyte.

### CROSS REFERENCE TO RELATED APPLICATIONS

This application claims the benefit of U.S. Provisional Patent Application Ser. Nos. 62/307,406, filed Mar. 11, 2016, the disclosure of which is incorporated herein by reference in its entirety.

### STATEMENT REGARDING FEDERALLY SPONSORED RESEARCH

This invention was made with United States Government support from the National Institute of Standards and Technology. The Government has certain rights in the invention.

### BRIEF DESCRIPTION

Disclosed is a dyadic sensor to sense an analyte, the dyadic sensor comprising: an analyte gate; a transition metal dichalcogenide layer disposed on the analyte gate and comprising a transition metal dichalcogenide; a source electrode disposed on the two-dimensional active layer and in electrical communication with the two-dimensional active layer; a drain electrode disposed on the two-dimensional active layer and in electrical communication with the two-dimensional active layer and in electrical communication with the source electrode via the two-dimensional active layer; and a control gate disposed on the two-dimensional active layer and controlling the communication of electrical current in the two-dimensional active layer between the source electrode and the drain electrode, wherein the electrical current communicated in the two-dimensional active layer is changed in response to a change in an electrical charge present at the analyte gate due to the analyte.

Also disclosed is a process for sensing an analyte, the process comprising: providing the dyadic sensor; subjecting the source electrode and the drain electrode with a first potential difference comprising a drain voltage; subjecting the control gate with a gate voltage; and monitoring a drain current to sense a presence of the analyte at the analyte gate.

### BRIEF DESCRIPTION OF THE DRAWINGS

The following descriptions should not be considered limiting in any way. With reference to the accompanying drawings, like elements are numbered alike.

FIG. 1 shows a perspective view of a dyadic sensor in panel A and a top view of the dyadic sensor in panel B;

FIG. 2 shows an exploded view of the dyadic sensor shown in FIG. 1;

FIG. 3 shows a cross-section along line A-A of the dyadic sensor shown in panel B of FIG. 1;

FIG. 4 shows a perspective view of a dyadic sensor;

FIG. 5 shows an exploded view of the dyadic sensor shown in FIG. 4;

FIG. 6 shows a top view of the dyadic sensor shown in FIG. 4 in panel A, and panel B shows a bottom view of the dyadic sensor shown in FIG. 4;

FIG. 7 a cross-section along line A-A of the dyadic sensor shown in panel B of FIG. 6;

FIG. 8 shows a perspective view of a dyadic sensor in panel A and a top view of the dyadic sensor in panel B;

FIG. 9 shows an exploded view of the dyadic sensor shown in FIG. 8;

FIG. 10 shows a cross-section along line A-A of the dyadic sensor shown in panel B of FIG. 8;

FIG. 11 shows a perspective view of a dyadic sensor;

FIG. 12 shows an exploded view of the dyadic sensor shown in FIG. 11;

FIG. 13 shows a top view of the dyadic sensor shown in FIG. 11 in panel A, and panel B shows a bottom view of the dyadic sensor shown in FIG. 11;

FIG. 14 a cross-section along line A-A of the dyadic sensor shown in panel B of FIG. 13;

FIG. 15 shows a perspective view of a dyadic sensor;

FIG. 16 shows a top view of the dyadic sensor shown in FIG. 15;

FIG. 17 shows an exploded view of the dyadic sensor shown in FIG. 15;

FIG. 18 shows a cross-section along line A-A of the dyadic sensor shown in FIG. 16; panel B shows a cross-section along line B-B of the dyadic sensor shown in FIG. 16, and panel C shows a cross-section along line C-C of the dyadic sensor shown in FIG. 16;

FIG. 19 shows a perspective view of a dyadic sensor;

FIG. 20 shows a top view of the dyadic sensor shown in FIG. 19;

FIG. 21 shows an exploded view of the dyadic sensor shown in FIG. 19;

FIG. 22 shows a cross-section along line A-A of the dyadic sensor shown in FIG. 19; panel B shows a cross-section along line B-B of the dyadic sensor shown in FIG. 19, and panel C shows a cross-section along line C-C of the dyadic sensor shown in FIG. 19;

FIG. 23 shows a dyadic sensor that includes an open loop detection in panel A, and panel B shows a graph of drain current versus gate voltage;

FIG. 24 shows a dyadic sensor that includes a closed loop detection in panel A, and panel B shows a graph of drain current versus gate voltage;

FIG. 25 shows steps for making a dyadic sensor;

FIG. 26 shows steps for making a dyadic sensor;

FIG. 27 shows steps for making a dyadic sensor;

FIG. 28 shows a dyadic sensor in panel A according to Example 1, and panel B shows a zoomed view the portion of the dyadic sensor shown in panel A;

FIG. 29 shows a graph of trained current versus drain voltage in panel A according to Example 2, and panel B shows a graph of trained current versus gate voltage;

FIG. 30 shows a graph of drain current versus time according to Example 3; and

FIG. 31 shows a dyadic sensor according to Example 4.

### DETAILED DESCRIPTION

A detailed description of one or more embodiments is presented herein by way of exemplification and not limitation.

It has been discovered that a dyadic sensor includes a field effect transistor (FET) having an analyte gate and a control gate that provides a reduction in noise and improved sensitivity as compared with a convention FET. The dyadic sensor detects, identifies, or to characterizes an analyte and generates an electronic signal in response to a presence of the analyte proximate to the analyte gate. The electronic signal can be, e.g., a change in a drain current across a two-dimensional active layer of the dyadic sensor. The change in the drain current can be proportional to the charge of the analyte. The electronic signal can be scaled to provide a gain characteristic of dyadic sensor to provide a high signal-to-noise ratio for sensing the analyte.

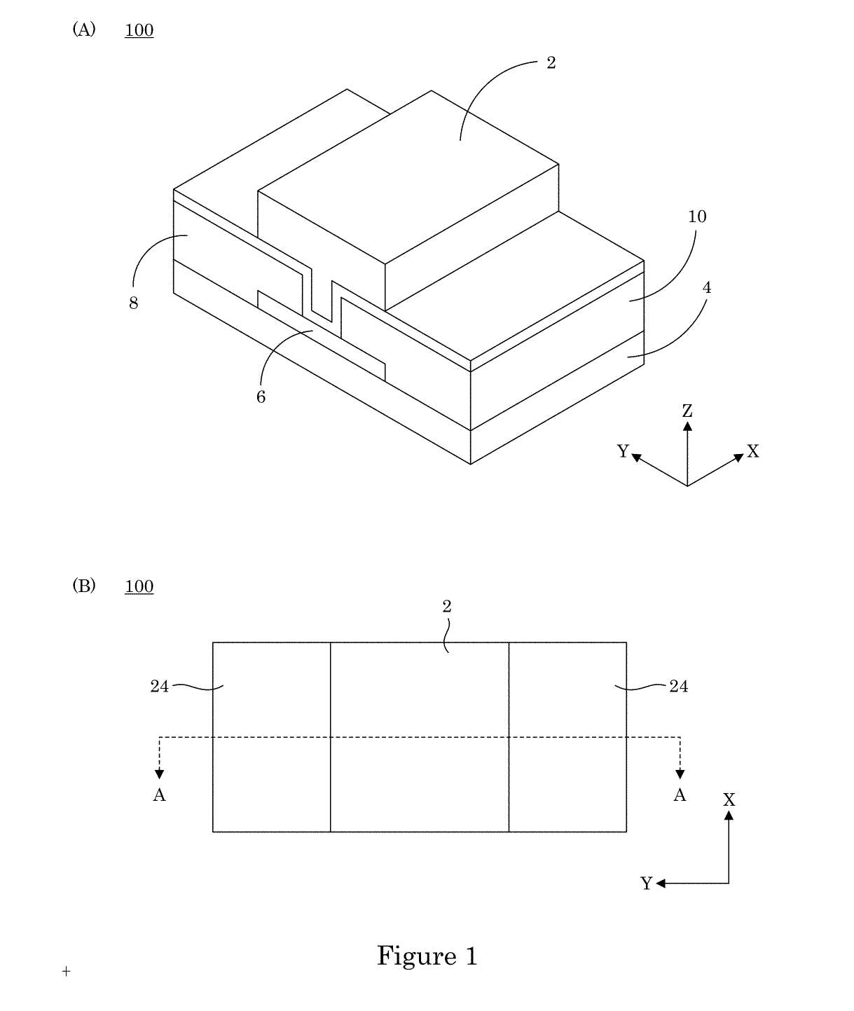

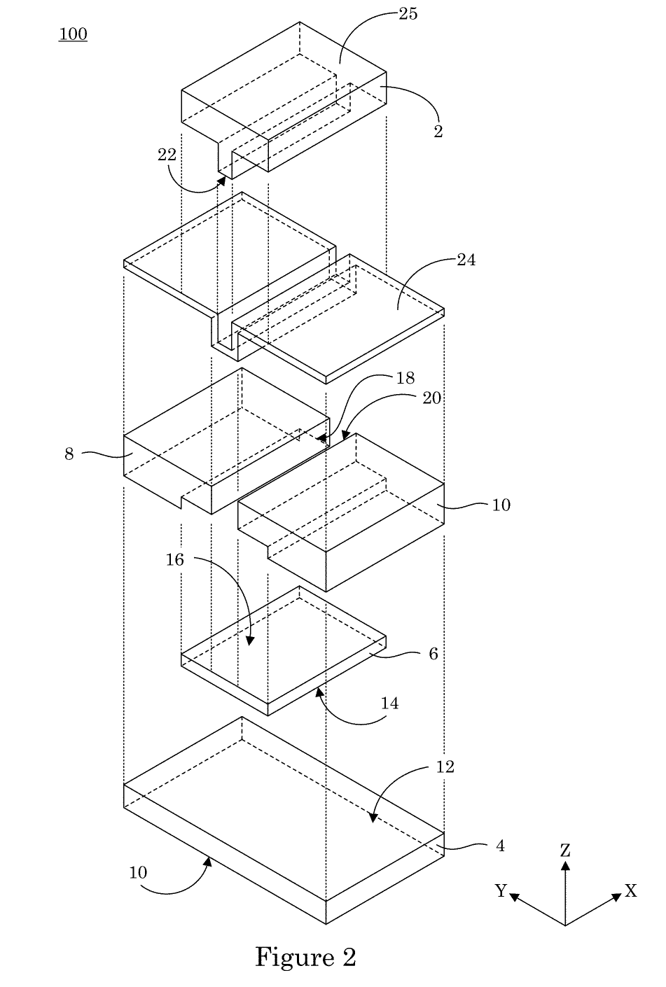

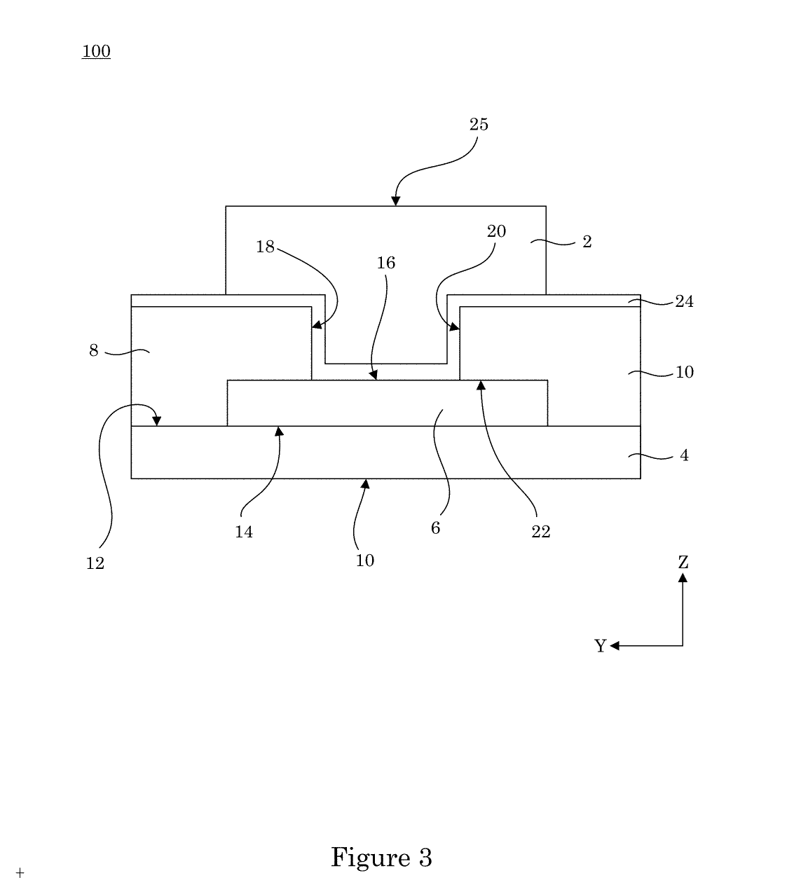

The dyadic sensor senses a change in an electric charge at an analyte gate due to the electric charge of an analyte. In an embodiment, with reference to FIG. 1 (perspective view in panel A and top view in panel B), FIG. 2 (exploded view), and FIG. 3 (cross-section along line A-A in panel B of FIG. 1); dyadic sensor 100 includes analyte gate 4; two-dimensional active layer 6 disposed on analyte gate 4 and including a transition metal dichalcogenide; source electrode 8 disposed on two-dimensional active layer 6 and in electrical communication with two-dimensional active layer 6; drain electrode 10 disposed on the two-dimensional active layer 6 and in electrical communication with two-dimensional active layer 6 and in electrical communication with source electrode 8 via two-dimensional active layer 6; and control gate 2 disposed on two-dimensional active layer 6 and controlling the communication of electrical current in two-dimensional active layer 6 between source electrode 8 and drain electrode 10, wherein the electrical current communicated in two-dimensional active layer 6 is changed in response to a change in an electrical charge present at analyte gate 4 due to analyte 58.

In an embodiment, dyadic sensor 100 includes gate insulating layer 24 interposed between control gate 2 and two-dimensional active layer 6 such that control gate 2 is bounded at channels surface 22 by wall 18 of source electrode 8, wall 20 of drain electrode 10, and control gate surface of two-dimensional active layer 6. Here, control gate 2 includes free surface 25. Moreover, two-dimensional active layer analyte gate surface 14 that opposes channel surface 12 of analyte gate 4. Further, analyte gate 4 includes analyte surface 10 on which analyte 58 can interact.

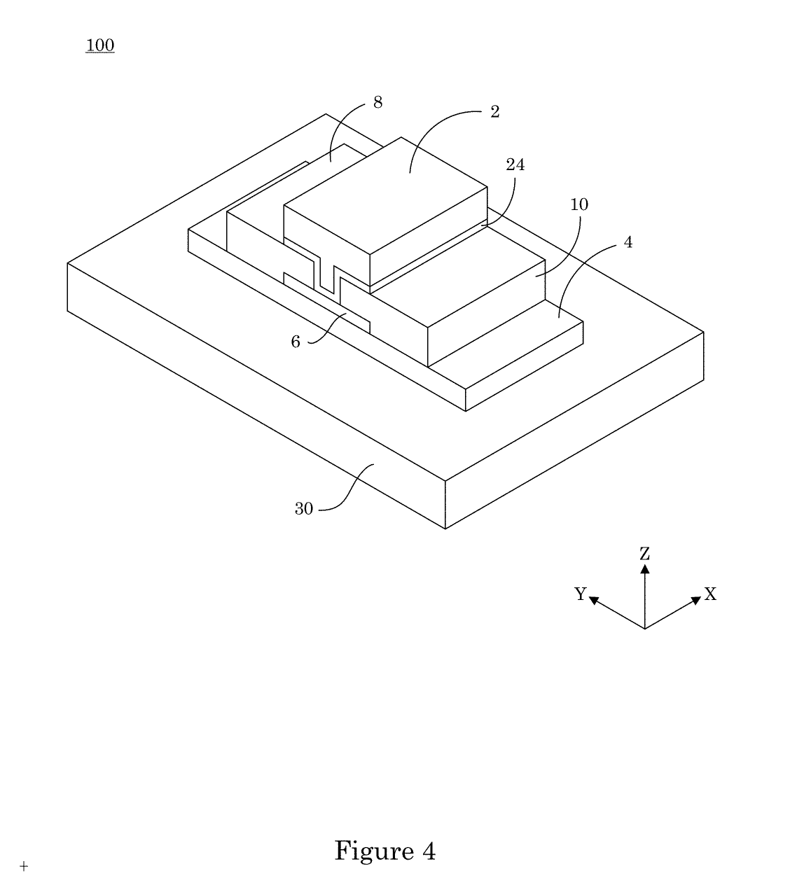

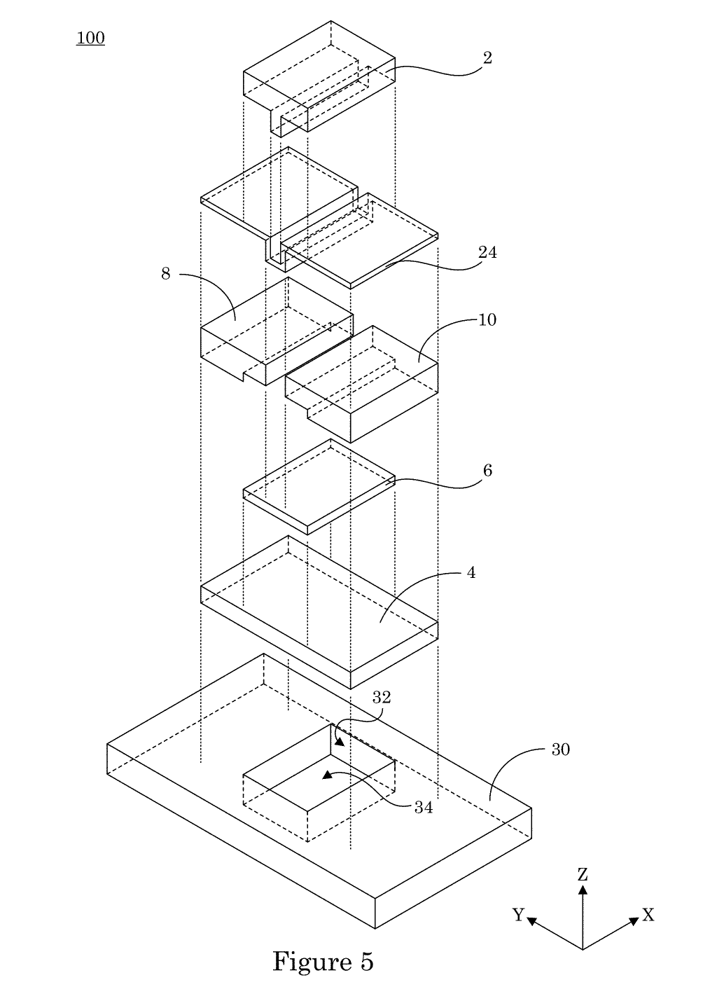

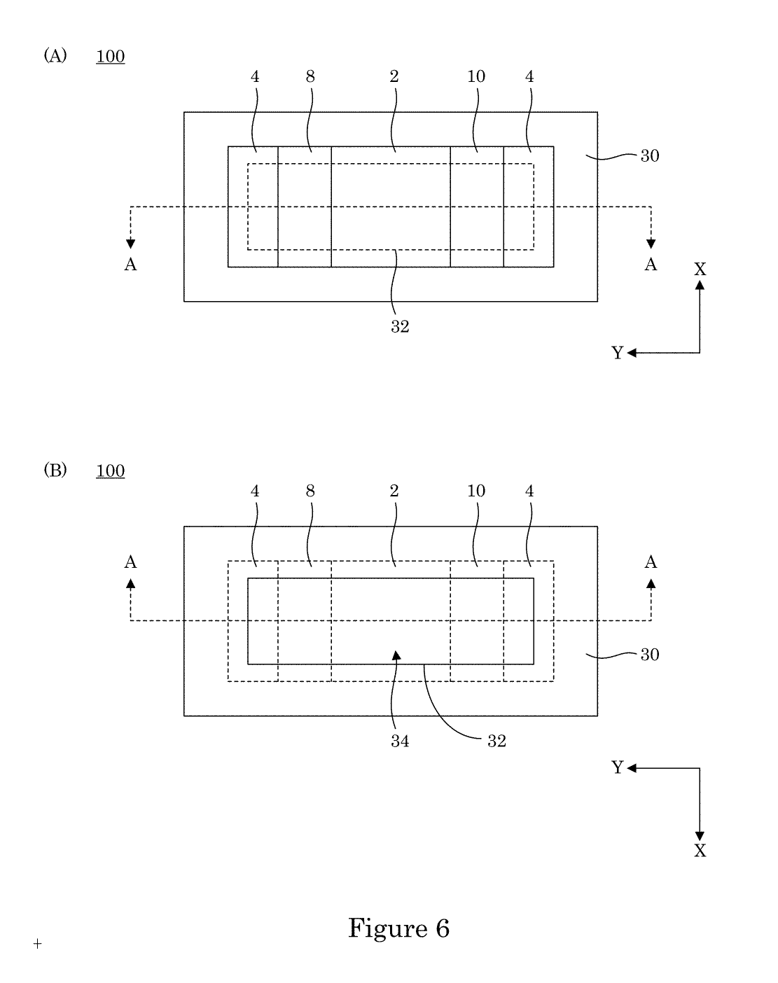

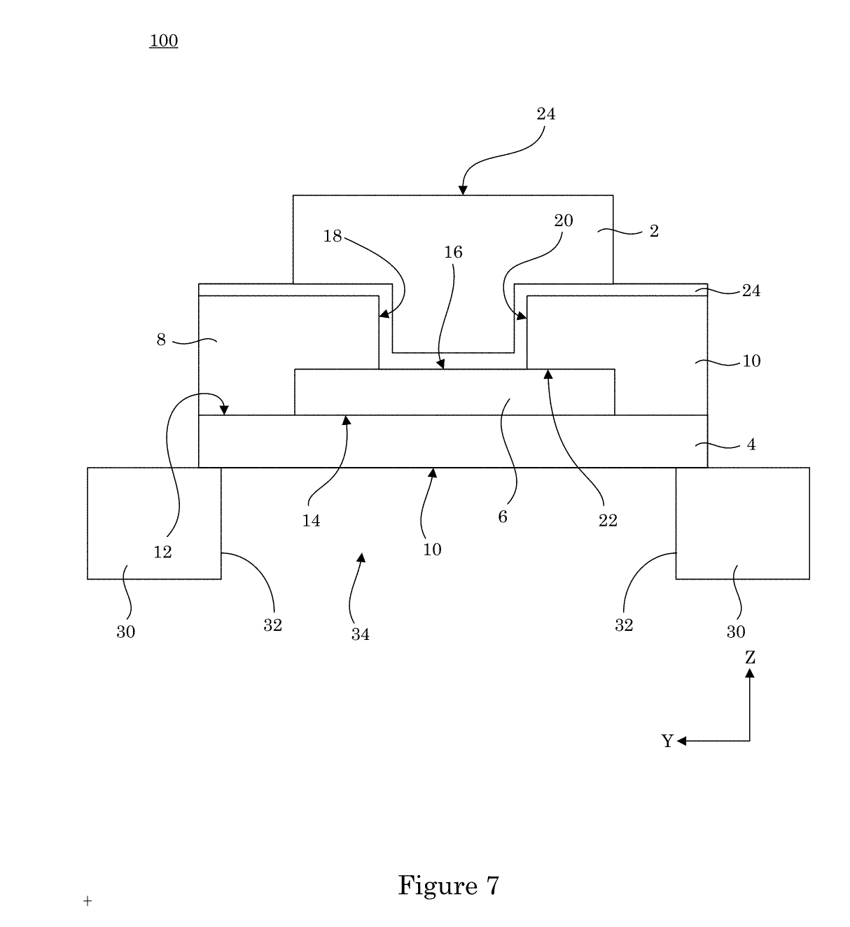

In an embodiment, with reference to FIG. 4 (perspective view) FIG. 5 (exploded view), FIG. 6 (top view in panel A and bottom view in panel B), and FIG. 7 (cross-section), dyadic sensor 100 includes substrate 30 on which analyte gate 4 is disposed, wherein analyte gate 4 is interposed between substrate 30 and two-dimensional active layer 6. As shown in FIG. 5 and FIG. 7, substrate 30 includes analyte chamber 34 bounded by wall 32. Analyte chamber 34 can receive analyte 58 for contact with analyte gate 4.

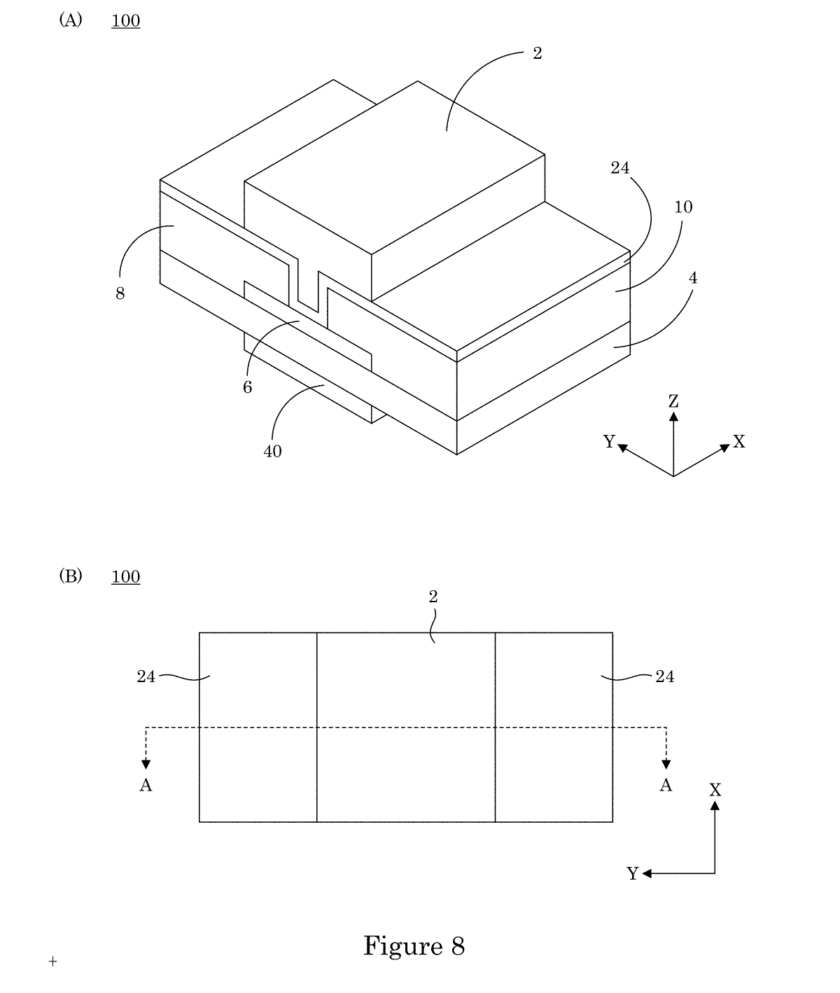

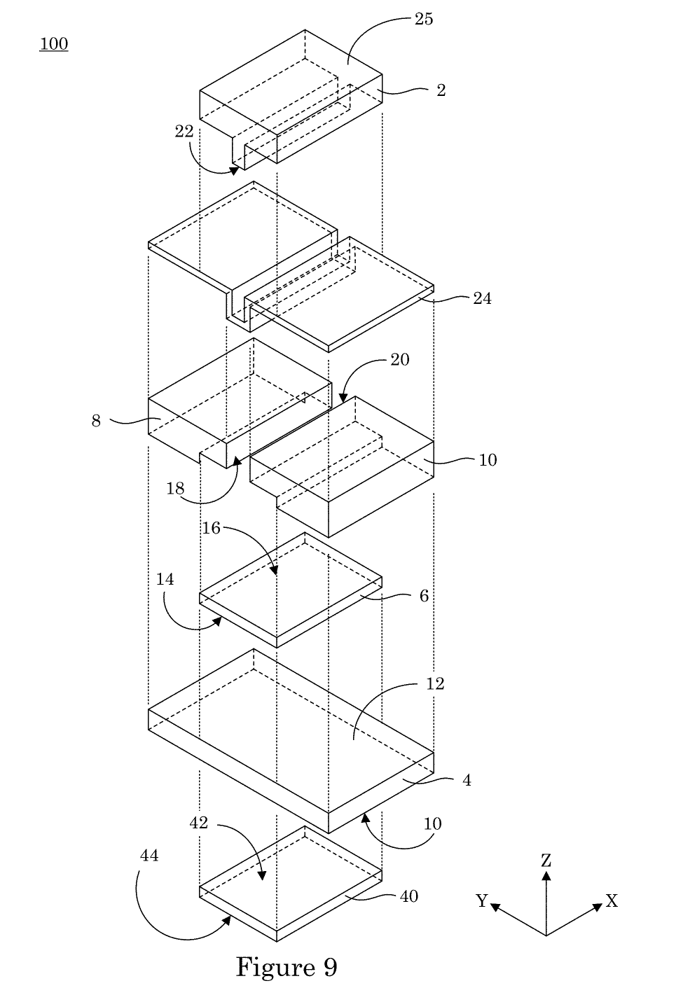

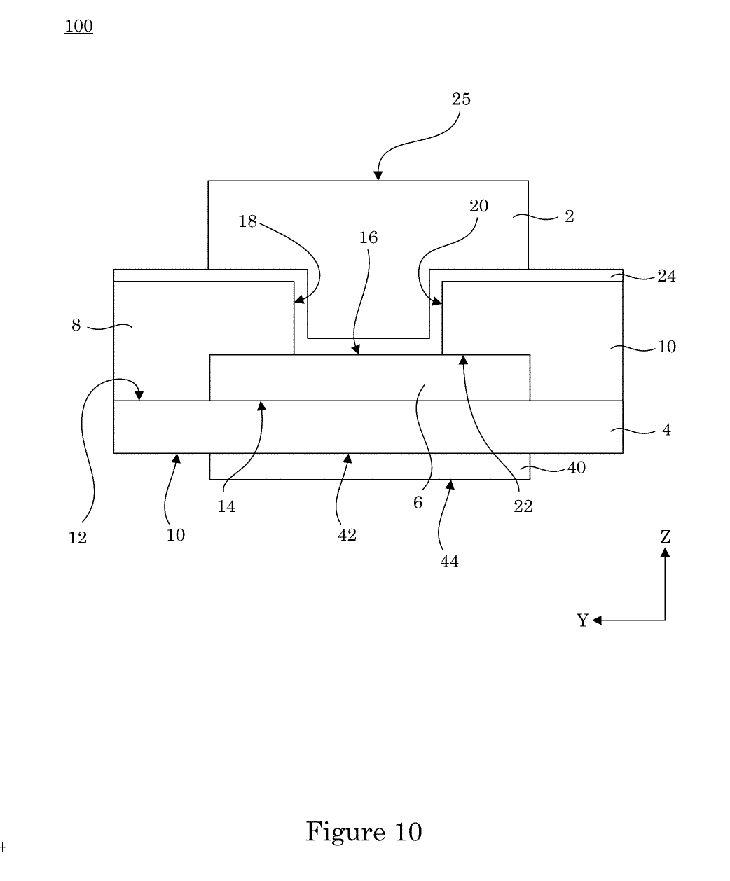

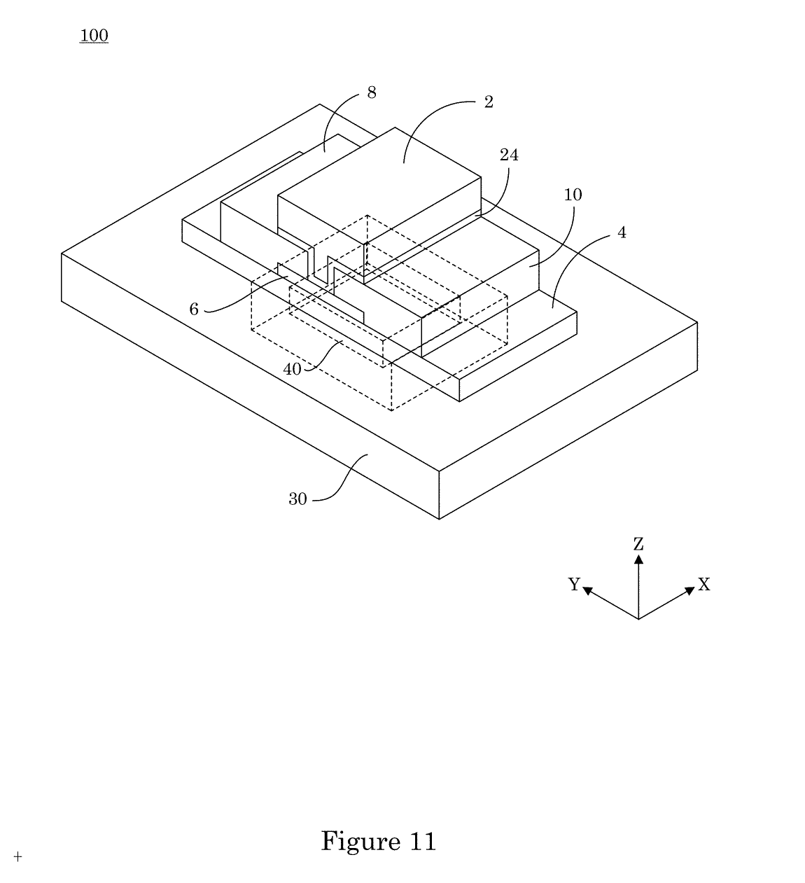

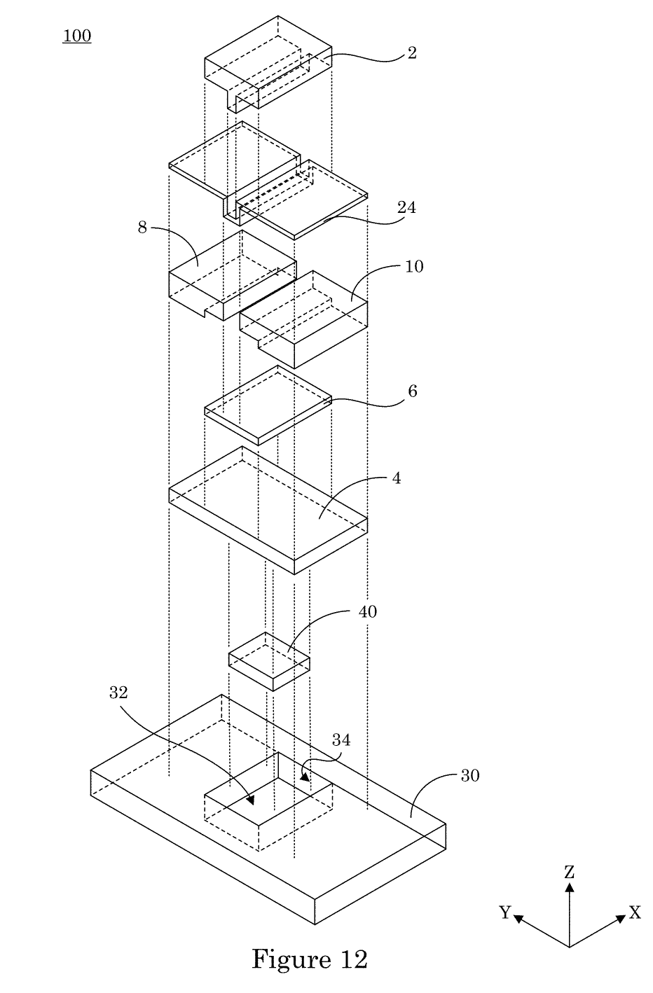

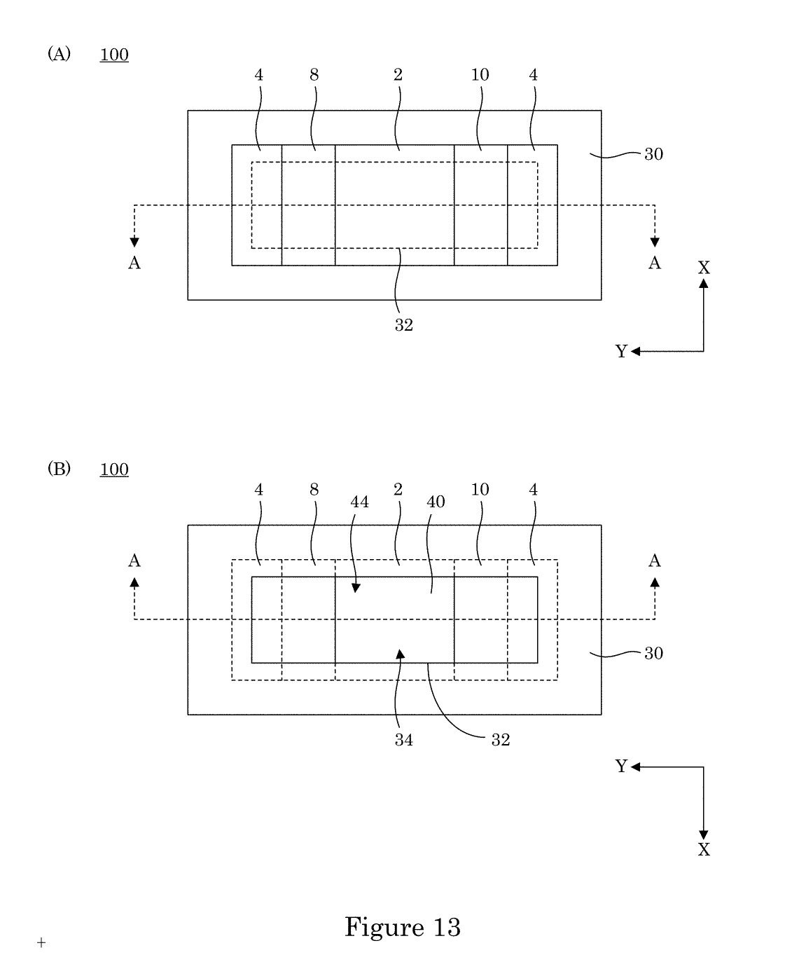

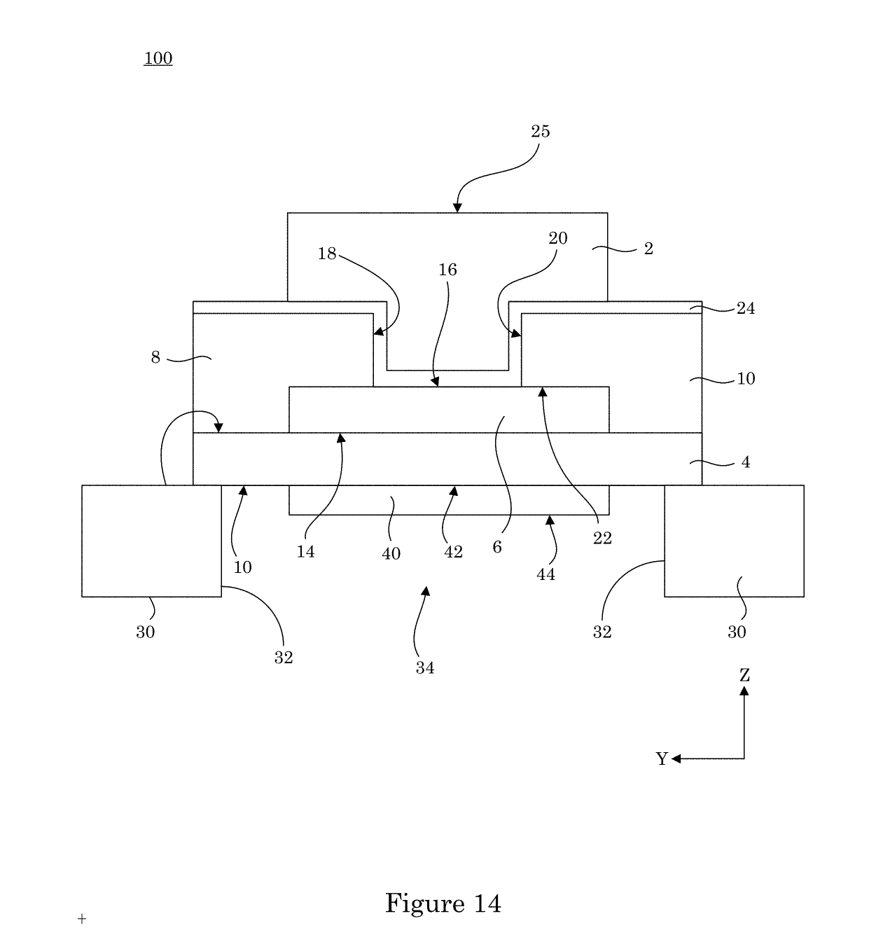

In an embodiment, with reference to FIG. 8, FIG. 9, and FIG. 10, dyadic sensor 100 includes analyte gate contact 40 disposed on analyte gate 4, wherein analyte gate 4 is interposed between analyte gate contact 40 and two-dimensional active layer 6. According to an embodiment, with reference to FIG. 11, FIG. 12, FIG. 13, and FIG. 14, dyadic sensor 100 further includes substrate 30 on which analyte gate 4 is disposed, wherein analyte gate 4 is interposed between two-dimensional active layer 6 and a combination of substrate 30 and analyte gate contact 40. Here, analyte gate contact 40 is disposed in analyte chamber 34 to receive analyte 58 at analyte contact surface 44 of analyte gate contact 40, wherein analyte gate contact 40 also includes gate contact surface 42 opposing analyte surface 10 of analyte gate 4.

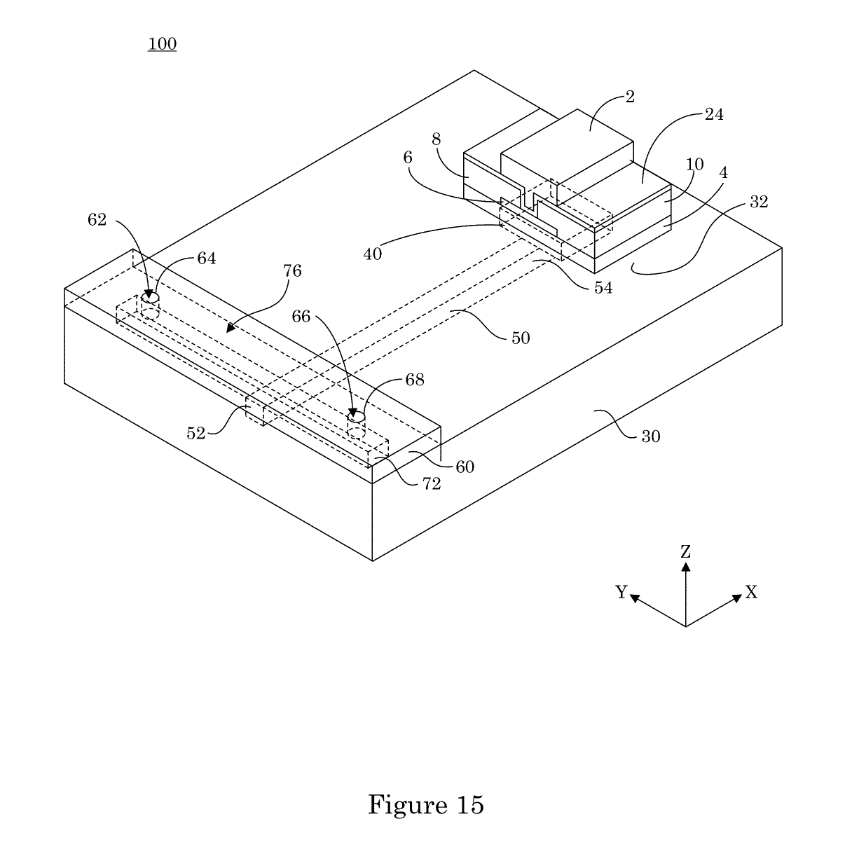

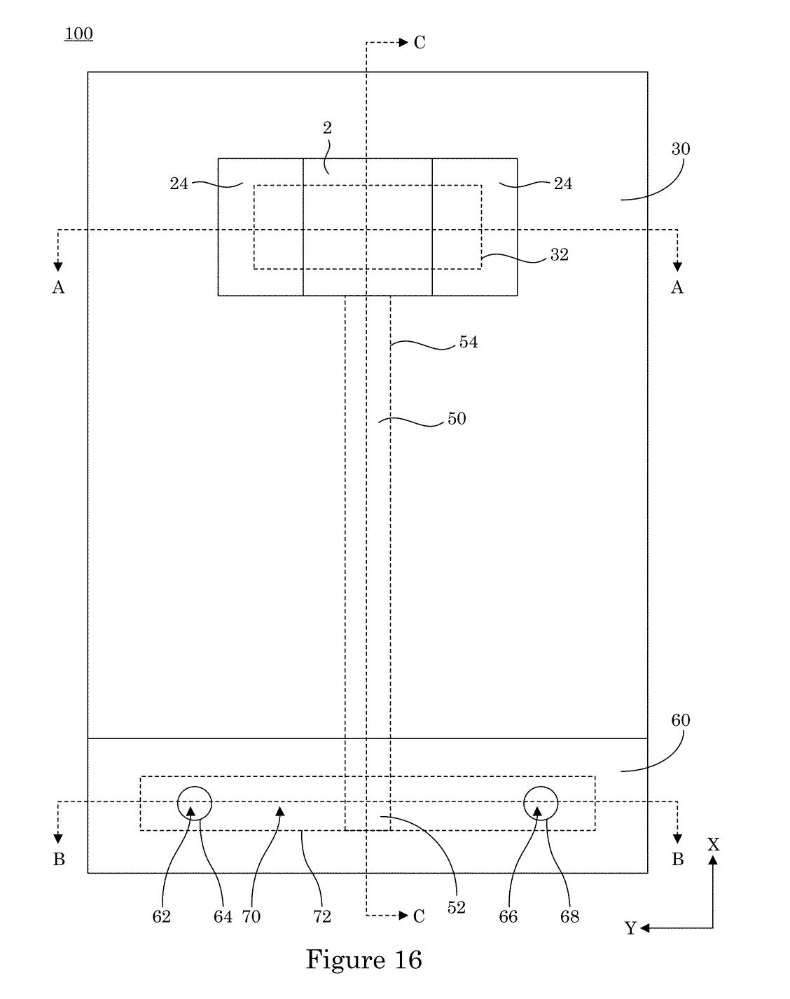

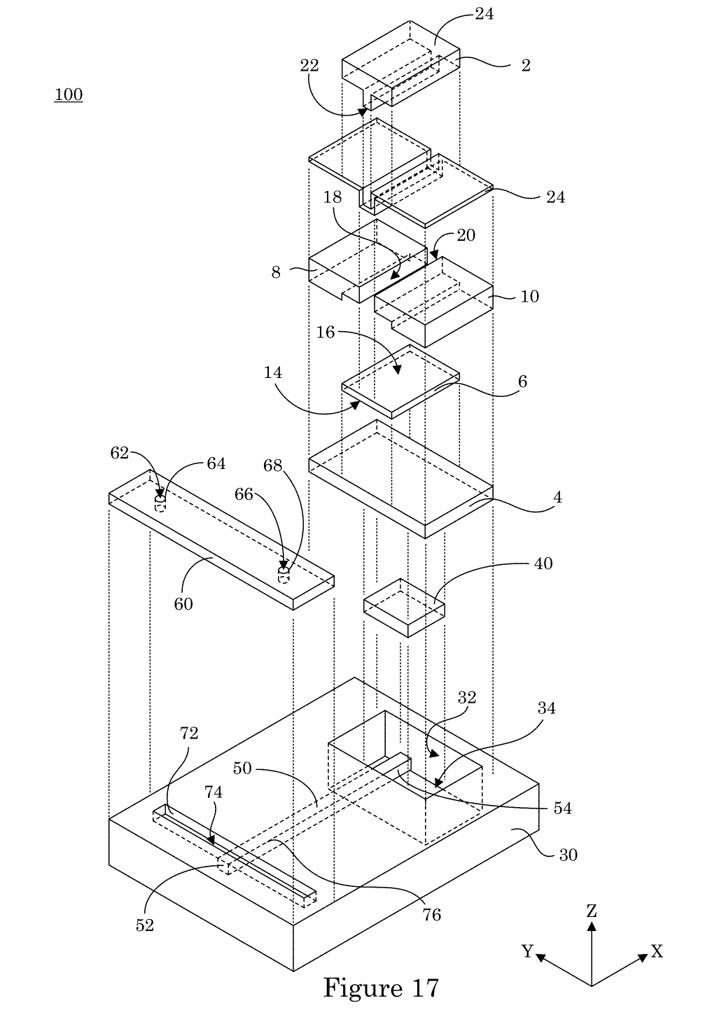

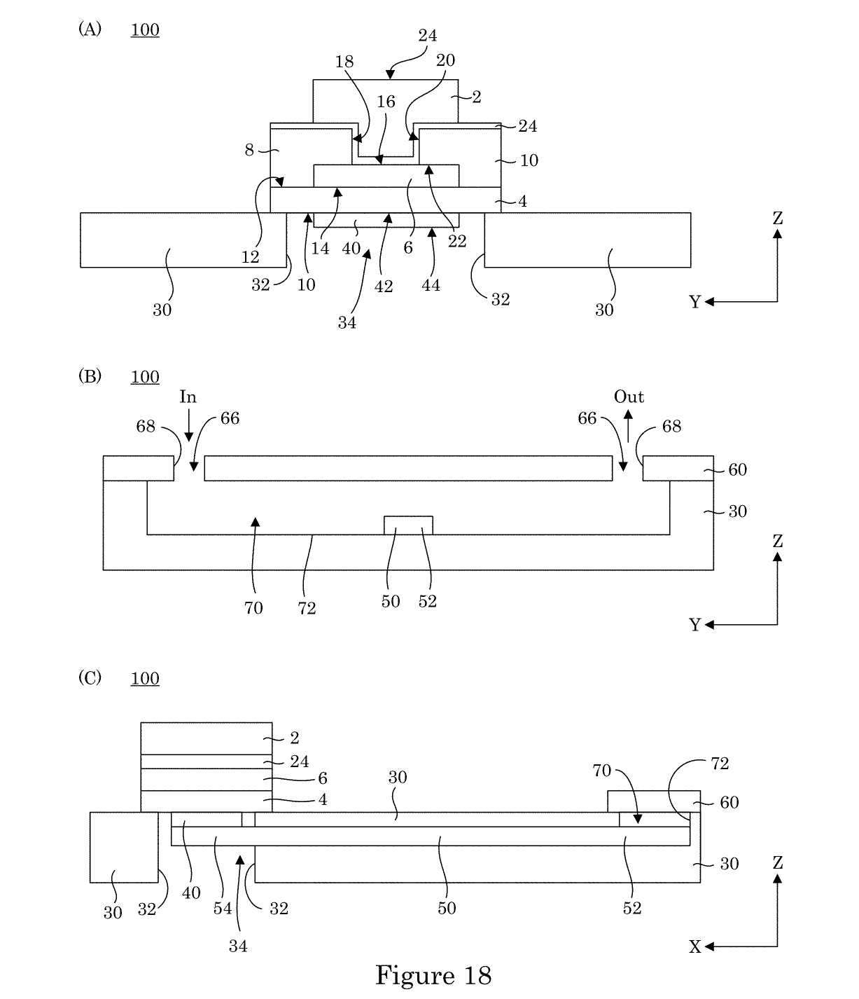

In an embodiment, with reference to FIG. 15, FIG. 16, FIG. 17, and FIG. 18, dyadic sensor 100 includes analyte gate extension 50 disposed on substrate 30 and in electrical communication with analyte gate contact 40. Here, analyte gate extension 50 includes first end connected to analyte gate contact 40 and second end 52 that extends on substrate 30 to microfluidic chamber 76 disposed on substrate 30. Microfluidic chamber 30 includes flow channel 70 bounded by wall 72 and cover 60. Cover 60 opposes an exposed surface of second end 52 of analyte gate extension 50 such that flow channel 70 provides for a flow of a fluid that includes analyte 58. Here, the exposed portion of second end 52 of analyte gate extension 50 in flow channel 70 can contact with analyte 58, and the electrical charge present at analyte gate 4 changes due to contact of analyte gate extension 50 with analyte 58. Flow of the fluid containing analyte 58 is introduced into flow channel 70 through inlet port 62 bounded by wall 64 disposed in cover 60. Flow of the fluid exits flow channel 70 through exit port 66 bounded by wall 68 disposed in cover 60. In this manner, the fluid traverses flow channel 70 so that analyte 58 can contact analyte gate extension 50 at second end 52. As shown in FIG. 17, it is contemplated that analyte gate extension 50 can extend along substrate 30 from analyte gate contact 40 at analyte gate 4 to microfluidic chamber 76 in channel 74 bounded by wall 76 of substrate 30.

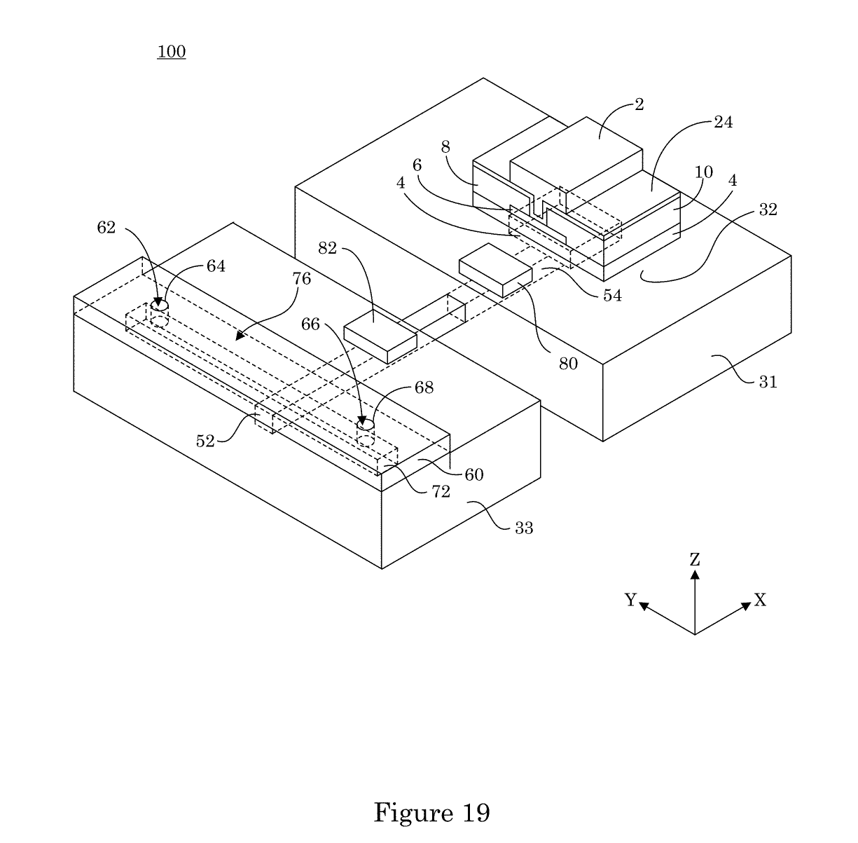

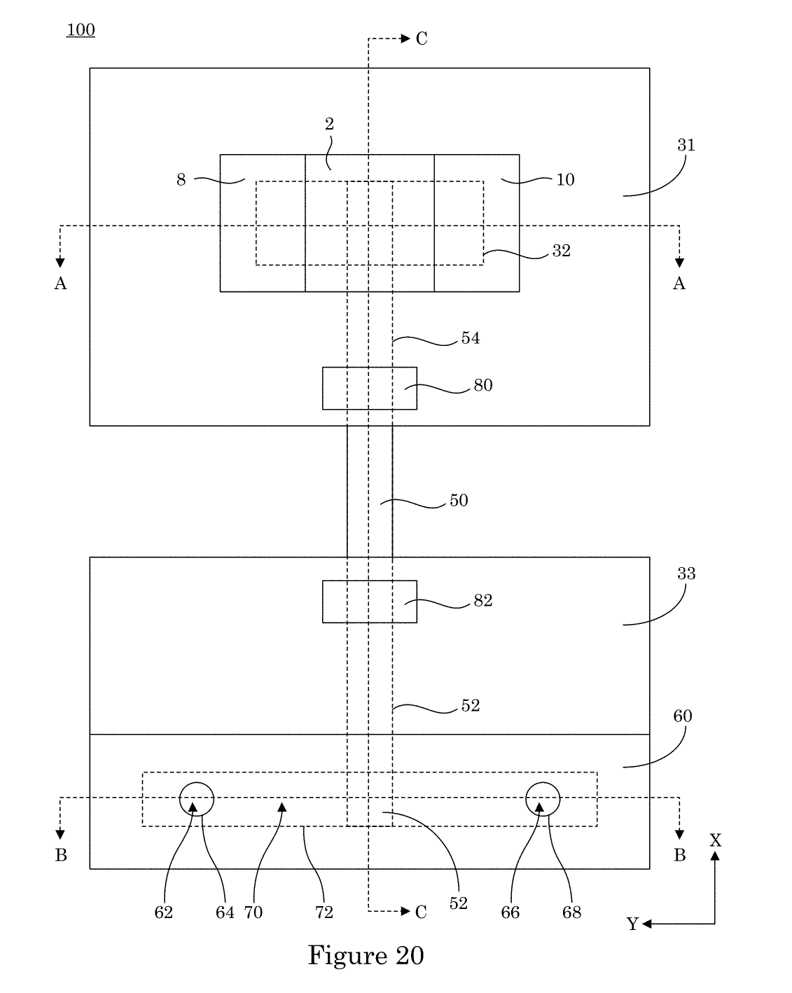

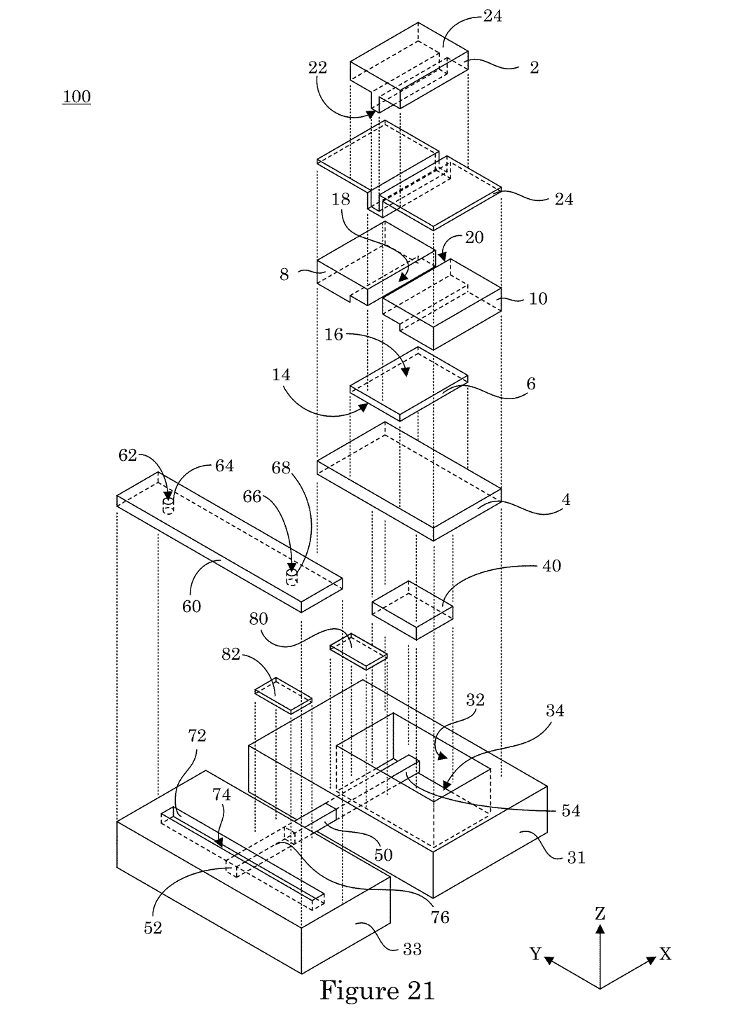

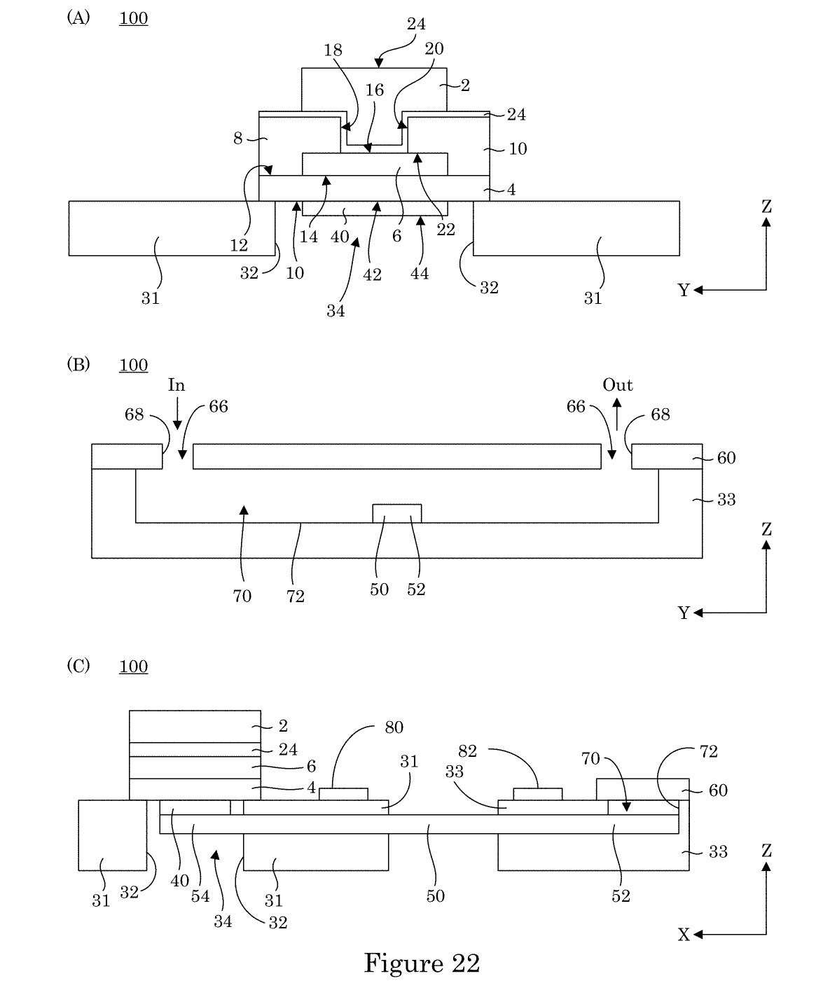

In an embodiment, with reference to FIG. 19, FIG. 20, FIG. 21, and FIG. 22, dyadic sensor 100 includes substrate 30 that includes first substrate 33 on which analyte gate 4 and analyte gate contact 40 are disposed; and second substrate 31 on which microfluidic chamber 76 is disposed. Here, first substrate 33 and second substrate 31 are spaced apart by distance D, and analyte gate extension 50 spans a separation between first substrate 33 and second substrate 31 across distance D. It is contemplated that first substrate 33 and second substrate 31 can be disposed on a common platform that supports first substrate 33 and second substrate 31, wherein first end 54 of analyte gate extension 50 is electrically connected to electrical pad 80 disposed on first substrate 33, and second end 52 of analyte gate extension 50 is electrically connected to electrical pad 82 disposed on second substrate 31.

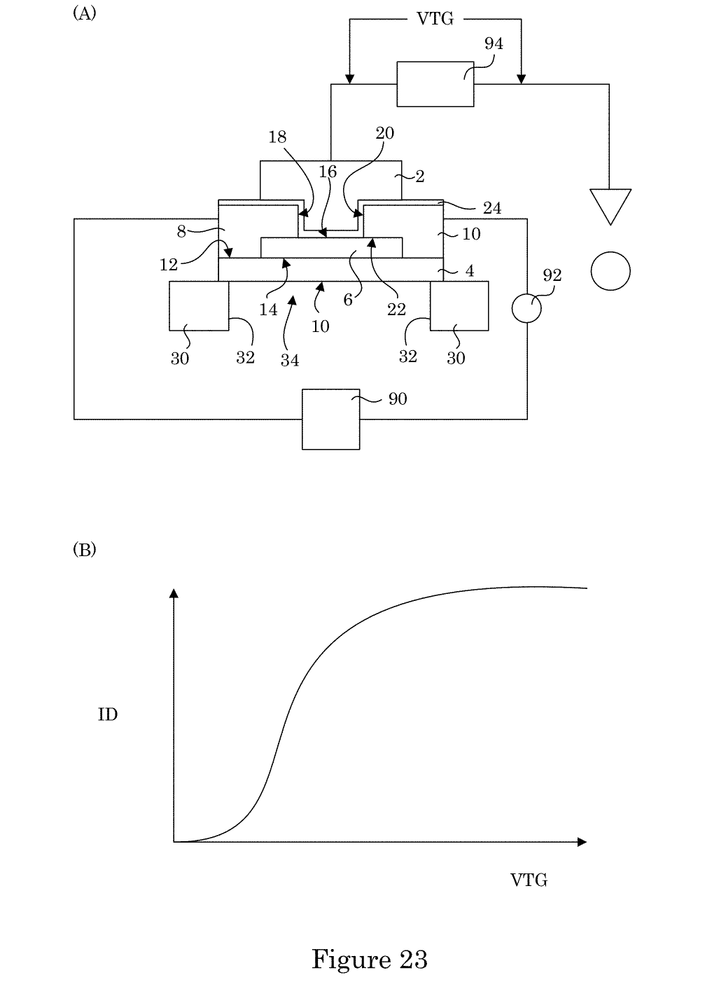

In an embodiment, with reference to FIG. 23, dyadic sensor 100 includes power source 90 in electrical communication with source electrode 8 and drain electrode 10 and provides a potential difference that includes drain voltage VD between source electrode 8 and drain electrode 10. Power source 94 is in electrical communication with control gate 2 to provide gate voltage VG to control gate 2. Monitor 92 is electrically interposed between, e.g., drain electrode 10 and power source 90 to monitor drain current ID communicated between source electro-8 and drain electrode 10 through two-dimensional active layer 6. In this manner, a presence of analyte 58 at analyte gate 4 can be sensed by dyadic sensor 100, e.g., by a change in drain current ID as shown panel B of FIG. 23. Here, dyadic sensor 100 is configure in an open loop mode. Accordingly, drain voltage VD is applied across source electrode 8 and drain electrode 10, and drain current ID across two-dimensional active layer 6 is acquired by monitor 92 (e.g., an ammeter). Also, gate voltage VG is applied to control gate 2 to control a density of carriers in two-dimensional active layer 6 and to provide flow of drain current ID between source electrode 8 and drain electrode 10. A graph of drain current ID versus gate voltage VG is shown in panel B of FIG. 23. It is contemplated that gate voltage VG can maintain dyadic sensor 100 in a sensitive detection region (e.g., S10 in panel B of FIG. 23) such that a relatively small change in gate voltage VG produces a relatively large change drain current ID. Analyte 58 proximate to analyte surface 10 of analyte gate 4 produces a change in drain current ID similar to changing gate voltage VG. A change in drain current ID is characteristic of analyte 58 interacting with dyadic sensor 100 via analyte gate 4. The change in drain current ID due to analyte 58 can be nulled by changing gate voltage VG to return drain current ID to an amount of current prior to the change in drain current ID due to analyte 58.

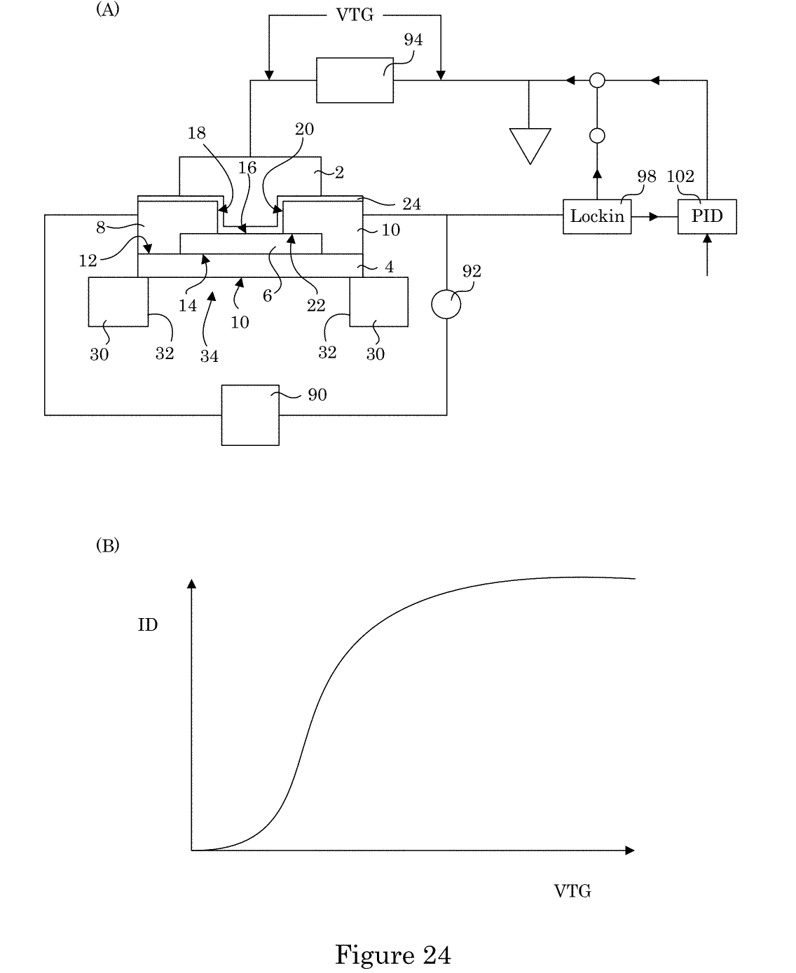

In an embodiment, with reference to FIG. 24, dyadic sensor 100 includes power source 90 in electrical communication with source electrode 8 and drain electrode 10 and provides a potential difference that includes drain voltage VD between source electrode 8 and drain electrode 10. Power source 94 is in electrical communication with control gate 2 to provide gate voltage VG to control gate 2. Monitor 92 is electrically interposed between, e.g., drain electrode 10 and power source 90 to monitor drain current ID communicated between source electro-8 and drain electrode 10 through two-dimensional active layer 6. In this manner, a presence of analyte 58 at analyte gate 4 can be sensed by dyadic sensor 100, e.g., by a change in drain current ID as shown panel B of FIG. 24. Additionally, dyadic sensor 100 can include frequency driver 98 (e.g., a lock-in amplifier) to control a frequency of gate voltage VG. Control loop feedback controller 102 can control an amplitude of gate voltage VG. Here, error signal 99 from frequency driver 98 can be provided to control loop feedback controller 102, wherein control signal 97 is communicated from control loop feedback controller 102 to power source 94 to control the amplitude of gate voltage VG. Control signal 97 changes in response to a change in error signal 99. Here, dyadic sensor 100 is configured in a closed loop mode. Accordingly, drain voltage VD is applied across source electrode 8 and drain electrode 10, and drain current ID across two-dimensional active layer 6 is acquired by monitor 92 (e.g., an ammeter). Also, gate voltage VG is applied to control gate 2 to control a density of carriers in two-dimensional active layer 6 and to provide flow of drain current ID between source electrode 8 and drain electrode 10. A graph of drain current ID versus gate voltage VG is shown in panel B of FIG. 24. It is contemplated that gate voltage VG can maintain dyadic sensor 100 in a sensitive detection region (e.g., S13 in panel B of FIG. 24) such that a relatively small change in gate voltage VG produces a relatively large change drain current ID. Analyte 58 proximate to analyte surface 10 of analyte gate 4 produces a change in drain current ID similar to changing gate voltage VG. A change in drain current ID is characteristic of analyte 58 interacting with dyadic sensor 100 via analyte gate 4. The change in drain current ID due to analyte 58 can be nulled by changing gate voltage VG to return drain current ID to an amount of current prior to the change in drain current ID due to analyte 58. Moreover, periodic signal 103 (e.g. sinusoidal, square, and the like) with an amplitude that is small in comparison the amplitude of gate voltage VG is generated by frequency driver 98 (e.g. a lock-in amplifier, function generator, and the like) and added to gate voltage VG. Output signal 105 that includes oscillations in drain current ID are communicated to an input channel of frequency driver 98 (e.g. a lock-in amplifier, phase sensitive detector, and the like) to generate DC error signal 99 that is proportional to any external disturbance, e.g., from analyte 58 proximate to analyte gate 4 of dyadic sensor 100. Error signal 99 is input to control loop feedback controller 102 (e.g. PID controller, nonlinear controller, and the like) to maintain drain current ID at a desired set point (e.g., S13 in panel B of FIG. 24) at a sensitive point of the graph. Moreover, control signal 97 produced control loop feedback controller 102, in response to a change in error signal 99 is recorded and is indicative of a binding event for analyte 58.

In an embodiment, dyadic sensor 100 includes an improved semiconductor/insulating interface structure formed by inclusion of two-dimensional active layer 6 in which two-dimensional active layer 6 can include a two-dimensional (2D) atomic crystal layer, Such a structure may be used, for example in a field effect device, e.g., a thin film transistor. Other embodiments include a method for forming such a structure and for forming a field effect device such as a thin film transistor structure in dyadic sensor 100.

Dyadic sensor 100 advantageously provide greater carrier mobility, lower power consumption due to reduction in leakage current, high temperature stability (e.g., up to 500° C.), lower cost as compared, e.g., with a conventional crystalline silicon field effect transistor. In an embodiment, a 10× to 20× greater mobility (e.g., up to and greater than 500 cm²/Vs) or 2 orders of magnitude lower power consumption due to the reduction in leakage current is provided.

In an embodiment, dyadic sensor 100 includes substrate 30 that can be any suitable dielectric or semiconductor material, e.g., silicon, glass, plastic, silicon, silicon on insulator, sapphire, and the like. Substrate 30 can be selected to support an interface between electronic and biological components as well as provide mechanical support for components of dyadic sensor 100. In an embodiment, substrate 30 includes a regular shaped surface. Exemplary substrates 30 include silicon, silicon dioxide on silicon, Al₂O₃ on Si, HfO₂ on Si, sapphire, silicon carbide, and the like. In an embodiment, substrate 30 is thermally grown silicon dioxide on silicon with a part of the underlying silicon removed to form analyte chamber 34. In an embodiment, substrate 30 includes silicon dioxide on silicon.

A thickness of substrate 30 can be from 100 nanometers (nm) to 1 centimeters (cm), specifically from 500 nm to 1 millimeter (mm), and more specifically from 1000 nm to 500 micrometers (μm).

Analyte gate 4 is provided in dyadic sensor 100 for changing drain current ID due to interaction with analyte 58. Exemplary materials for analyte gate 4 includes a dielectric material such as Al₂O₃, Hf₂O₂, SiO₂, hexagonal boron nitride, and the like. In an embodiment, analyte gate 4 includes analyte surface 10 that can include be a chemical interface to promote adhesion of analyte 58 thereto. Analyte surface 10 improves selectivity of dyadic sensor 100 for analyte 58.

A thickness of analyte gate 4 can be from 1 nm to 300 nm, specifically from 1 nm to 30 nm, and more specifically from 2 nm to 10 nm.

It is contemplated that analyte gate contact 40 can be disposed on analyte gate 4. Exemplary materials for analyte gate 4 include silicon dioxide on silicon, Al₂O₃ on Si, HfO₂ on Si, sapphire, silicon carbide, and the like, Analyte gate extension 50 can be connected to analyte gate contact 40. In this manner, analyte gate contact 40 or analyte gate extension 50 can interact (e.g., contact) analyte 58 and communicated a change in electrical charge to analyte gate 4, wherein analyte gate 4 produces a change in drain current ID between source electrode 8 and drain electrode 10. Further, electrical pads (e.g., 80, 82) can be disposed on substrate 30 and in electrical contact with analyte gate contact 40 or analyte gate extension 50. It should be appreciated that analyte gate contact 40 or analyte gate extension 50, pads (80, 82) are electrically conductive and can include an electrical conductor such as a metal, e.g., titanium, gold, silver, aluminum, nickel, chrome, and the like, or a combination thereof.

A thickness of analyte gate contact 40 and analyte gate extension 50 independently can he from 20 nm to 300 nm, specifically from 50 nm to 200 nm, and more specifically from 50 nm to 100 nm.

Source electrode 8 and drain electrode 10 are disposed on two-dimensional active layer 6 to produce drain current ID that changes due to application of gate voltage VG to control gate 2 and a presence of analyte 58 at analyte gate 4, analyte gate contact 40, or analyte gate extension 50, It should be appreciated that source electrode 8 and drain electrode 10 are electrically conductive and can include an electrical conductor such as a metal, e.g., titanium, gold, silver, aluminum, nickel, chrome, and the like, or a combination thereof. A thickness of source electrode 8 and drain electrode 10 independently can be from 20 nm to 300 nm, specifically from 50 nm to 200 nm, and more specifically from 50 nm to 100 nm.

Control gate 2 is disposed on two-dimensional active layer 6 to control production of drain current ID via application of gate voltage VG to control gate 2 or presence of analyte 58 at analyte gate 4, analyte gate contact 40, or analyte gate extension 50. It should be appreciated that control gate 2 is electrically conductive and can include an electrical. conductor such as a metal, e.g., titanium, gold, silver, aluminum, nickel, chrome, and the like, or a combination thereof. A thickness of control gate 2 can be from 20 nm to 300 nm, specifically from 50 nm to 200 nm, and more specifically from 50 nm to 100 nm.

Gate insulating layer 24 is interposed between control gate 2 and two-dimensional active layer 6 to electrically isolate control gate 2 from two-dimensional active layer 6. It is contemplated that gate insulating layer 24 can be interposed between control gate 2 and drain electrode 10, control gate 2 and source electrode 8, or a combination thereof for electrical isolation. In some embodiments, gate insulating layer 24 is a high dielectric constant (“high-k”) insulator layer. in some embodiments, the high-k insulator layer has a high-k value from 10 to 40 e₀. In some embodiments, the high-k insulator layer has a high k-value greater than 40 e₀. Exemplary material for gate insulating layer 24 includes an electrical insulator such as Al₂O₃, Hf₂O₂, SiO₂, hexagonal boron nitride, and the like, or a combination thereof. A thickness of gate insulating layer 24 can be from 1 nm to 300 nm, specifically from 1 nm to 30 nm, and more specifically from 2 nm to 10 nm.

Two-dimensional active layer 6 is interposed. between control gate 2 and analyte gate 4. Two-dimensional active layer 6 can he a 2D atomic crystal layer with a crystalline atomic plane produced either from a bottom-up synthesis process (e.g. Van-der-Waals epitaxial growth), extracted, cleaved, or the like from a constituent bulk crystal. In some embodiments, an individual crystalline atomic plane is cleaved from a bulk homogeneous crystal structure. In some embodiment, two-dimensional active layer 6 is provided by cleaving a heterogeneous crystal. structure. The cleaving process can be accomplished, e.g., by mechanical exfoliation, chemical exfoliation, or a combination thereof. The crystalline atomic plane of two-dimensional active layer 6 has a generally two-dimensional (2D) structure in x- and y-directions and a very small depth in the z-direction relative to its dimensions in the x-y plane (i.e., Dₓ, D_{y}>>D_{z}). The 2D atomic crystals includes transition metal dichalcogenide (TMD) that provides a semiconducting structure and according semiconducting electrical properties. Additional 2D atomic crystals include black phosphorous, graphene oxide, indium selenide, silecene, and the like, or a combination thereof.

TMD can be arranged in an atomically thin monolayer having a chemical formula MX₂, wherein M a transition metal, and X is a chalcogenide of a chalcogen (e.g., O, S, Se, Te, and the like) from group 16 of the periodic table of elements. M can be, e.g., a transition metal of Group 3 (e.g., Sc, Y, and the like), Group 4 (e.g., Ti, Zr, Hf, and the like), Group 5 (e.g., V, Nb, Ta, and the like), Group 6 (e.g., Cr, Mo, W, and the like), Group 7 (e.g., Mn Re, and the like), Group 8 (e.g., Fe, Ru, Os, and the like), Group 9 (e.g., Co, Rh, Ir, and the like), Group 10 (e.g., Ni, Pd, Pt, and the like), Group 11 (e.g., Cu, Ag, Au, and the like), Group 12 (e.g., Zn, Cd, Hg, and the like), and the like, or a combination thereof. Alloyed forms of TMDs can be included in two-dimensional active layer 6 and can include a chemical formula MₘM′₁₋ₘX₂, wherein M and M′ are different transition metals, and 0<m<1; MX_{X}X′₂₋ₓ, wherein X and X′ are different chalcogenides, and 0<x<2; and MₘM′₁₋ₘX_{X}X′₂₋ₓwhere M and M′ are different transition metals, X and X′ are different chalcogenides, and 0<m<1, and 0<x<2. Doped forms of TMDs can be included in two-dimensional active layer 6 and can include alkali metal-doped forms of TMDs. More generally, M can be any combination of one or more transition metals, X can be any combination of one or more of S, Se, and Te, and the chemical formula can be represented as MX_{y}, where y is 2 or about 2. In some embodiments, TMD in two-dimensional active layer includes transition metal M that is a Group 6 transition metal (e.g., Mo or W).

Exemplary semiconducting transition metal dichalcogenides for two-dimensional active layer 6 include molybdenum disulfide (MoS₂), tungsten disulfide (WS₂), niobium disulfide (NbS₂), tantalum disulfide (TaS₂), vanadium disulfide (VS₂), rhenium disulfide (ReS₂), tungsten selenide (WSe₂), molybdenum selenide (MoSe₂), niobium selenide (NbSe₂), or the like. Without wishing to be bound by theory, transition metal dichalcogenides having group 4 and 6 transition metals (e.g., Mo, Hf, W) exhibit superconducting, semiconducting or insulating properties, depending on the band-gap of the material. The unfilled transition-metal d-band determines the band-gap, the dielectric constant, and mobility of the transition metal dichalcogenides.

Two-dimensional active layer 6 can be a single monolayer, double monolayer, triple monolayer, or the like. It is contemplated that a thickness of gate insulating layer 24 can be from 1 nm to 300 nm, specifically from 1 nm to 30 nm, and more specifically from 2 nm to 10 nm.

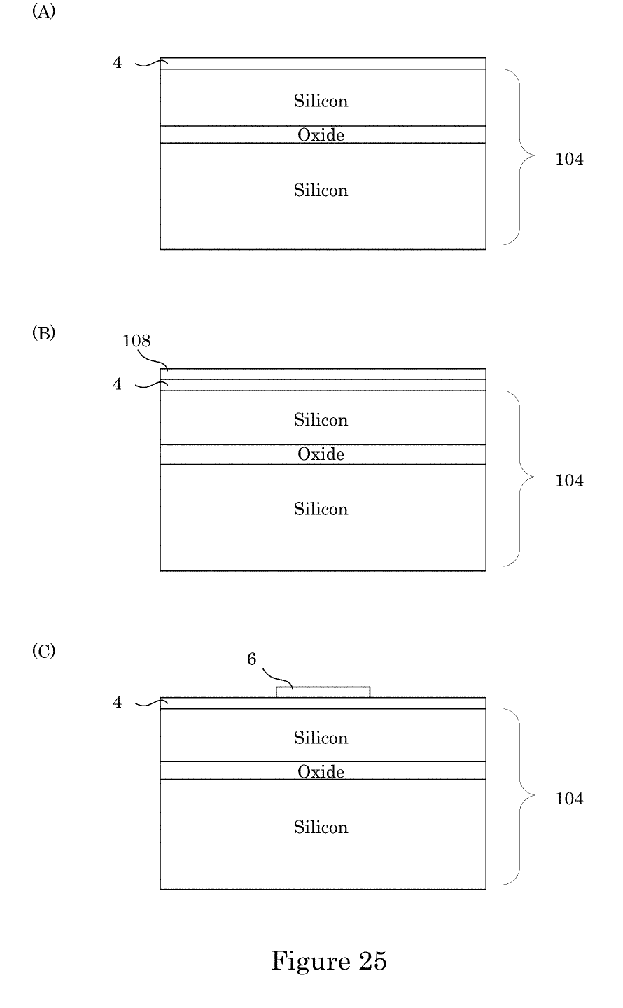

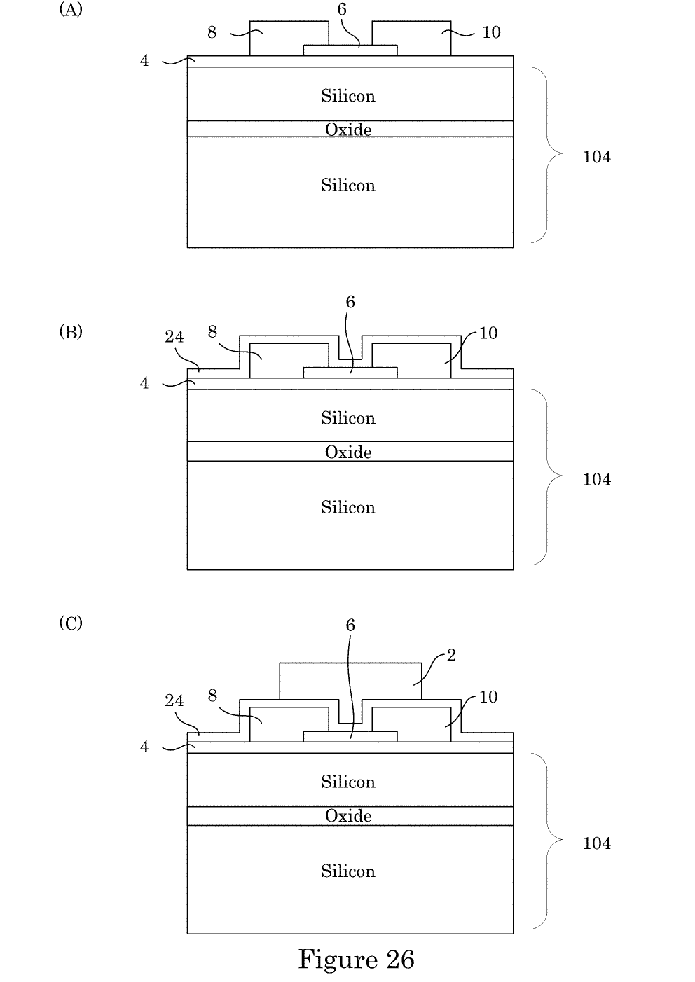

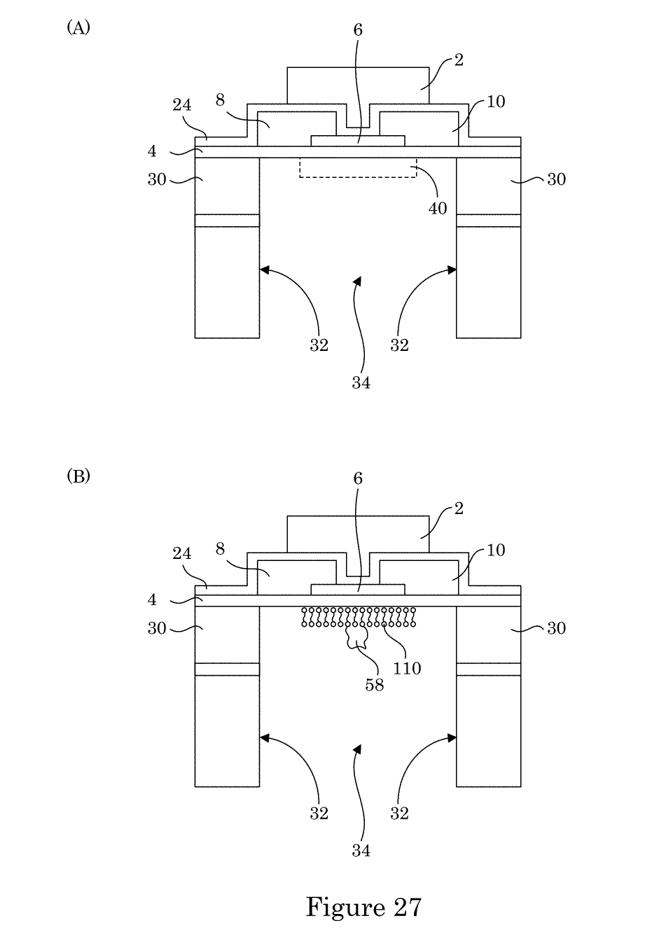

In an embodiment, with reference to FIG. 25, FIG. 26, and FIG. 27, a process for making dyadic sensor 100 includes providing substrate layer 104 that can include, e.g., a silicon on insulator (SOI) material in which a silicon oxide layer is interposed between layers of silicon. Analyte gate 4 (e.g., as an oxide film) is disposed on substrate layer 104 as shown in panel A of FIG. 25. The oxide film can include, e.g., SiO₂, Al₂O₃, HfO₂, and the like and can be deposited on substrate layer 104 via a thermal process, atomic layer deposition, and the like. As shown in panel B of FIG. 25, TMD is disposed as film layer 108 on analyte gate 4. Film layer 108 can be produced from an exfoliated material, deposited by chemical vapor deposition, and the like. As shown in panel C of FIG. 25, two-dimensional active layer 6 is defined lithographically, wherein TMD outside the lithographically defined is etched using, e.g. by reactive ion etching or the like, to prepare two-dimensional active layer 6. Thereafter, as shown in panel A of FIG. 26, source electrode 8 and drain electrode 10 is defined lithographically from a metal layer (not shown) that includes an electrically conductive material (e.g., gold, silver, platinum, and the like) and deposited on two-dimensional active layer 6 to form source electrode 8 and drain electrode 10. Gate insulating layer 24 is formed by deposition of a film of oxide (e.g. SiO₂, Al₂O₃, HfO₂, etc.) via, e.g., atomic layer deposition to cover two-dimensional active layer 6, source electrode 8, and drain electrode 10 with gate insulating layer 24 as shown in panel B of FIG. 26. Panel C of FIG. 26 disposal of control gate 2 on two-dimensional active layer 6, source electrode 8, and drain electrode 10 that occurs subsequent to lithographic definition of control gate 2 so on two-dimensional active layer 6, source electrode 8, and drain electrode 10. Control gate 2 can be disposed by deposition of an electrically conductive material. As shown in panel A of FIG. 27, substrate 30 is formed by removing (e.g., by etching) part of substrate layer 104 to exposed analyte surface 10 of analyte gate 4 to form dyadic sensor 100, wherein etching can be proceeded by lithographically defining the area for removal. Substrate layer 4 can be etched by deep reactive ion etching, TMAH etching, BOE etching, XeF2 etching, and the like, or a combination thereof. Optionally analyte gate contact 40 can be disposed on analyte surface 10 of analyte gate 4 by metal deposition of an electrically conductive material. Further, analyte gate extension 50 optionally can be disposed on substrate 30 in electrical communication with analyte gate 4 by metal deposition of an electrically conductive material in receiver 74 (see FIG. 17) formed by etching substrate 30. Likewise, microfluidic chamber can be formed by etching substrate 30 to form flow channel 30 and disposing cover 60 over flow channel 30 with mechanical pressure, adhesive, or the like.

In an embodiment, as shown in panel B of FIG. 27, the process also can include disposing adsorbant 110 on analyte gate 4 or analyte gate contact 40. Adsorbant 110 provides interaction with analyte 58. Such interaction improves selectivity of dyadic sensor 100 with respect to sensing analyte 58. Exemplary adsorbants 110 include a diffusive barrier (e.g., a polymer, lipids, and the like), biomolecule (e.g., a receptor protein, nucleic acid (DNA, RNA, and the like), antibody, and the like), and the like that interact with analyte 58 with high selectivity.

Dyadic sensor 100 has numerous beneficial uses, including sensing analyte 58. In an embodiment, process for sensing an analyte includes providing dyadic sensor 100; subjecting source electrode 8 and drain electrode 10 with a first potential difference comprising drain voltage VD; subjecting control gate 2 with gate voltage VG; and monitoring drain current ID to sense a presence of analyte 58 at analyte gate 4. As used herein, “sensing” can include detection of the presence of one or more analytes, measurements of the interaction between two or more analytes, detecting conformational or structural changes in one or more analytes, detecting chemical changes that lead a change in net charge of one or more analytes. The process can further include controlling a frequency of gate voltage VG with frequency driver 98, wherein monitoring drain current ID includes detecting drain current ID at the frequency of gate voltage VG. The process also can include controlling an amplitude of gate voltage VG with control loop feedback controller 102. In some embodiments, the process includes providing error signal 99 from frequency driver 98 to control loop feedback controller 102; and providing control signal 97 from control loop feedback controller 102 to control the amplitude of gate voltage VG, wherein control signal 97 changes in response to a change in error signal 99. Acquisition of the drain current ID can be accomplished by a parameter analyzer, ammeter, analog to digital convertor, or oscilloscope. Additionally, a set point can be supplied to control loop feedback controller 102 by a digital input or analog voltage source.

Dyadic sensor 100 has numerous advantageous and beneficial properties. In an aspect, dyadic sensor 100 is a dyadic sensor, wherein drain current ID through two-dimensional active layer 6 changes in response to and depends upon volt gate VG applied to control gate 2 and the charge present at analyte gate 4. Moreover, dyadic sensor 100 can be an asymmetric sensor, wherein control gate 2 is a different material than analyte gate 4. In an embodiment, control gate 2 is electrically conductive, and analyte gate 4 is dielectric. It is contemplated that dyadic sensor 100 can be a symmetric sensor, wherein control gate 2 is a same material as analyte gate 4. Further, dyadic sensor 100 provides sensitive detection and quantification of analytes due to the presence of a separate control gate 2, wherein dyadic sensor 100 can be disposed at a point of optimal sensitivity, in an absence of decreasing sensitivity from adsorption of analyte 58 to the surface of analyte gate 4.

Advantageously, unexpectedly, and surprisingly, dyadic sensor 100 is a dual gate article and includes control gate 2 to control two-dimensional active layer 6 and also includes analyte gate 4 that can be a thin membrane layer disposed over analyte chamber 34 (a fluidic chamber for flow or disposal of analyte 58 on analyte gate 4). Beneficially, analyte gate contact 40 can be disposed on analyte gate 4 and can be a second metal gate electrode that is superior to a conventional chem FET or floating gate FET, which adsorb molecules on a metal top gate. Because chem FET or floating gate FET has a thick gate dielectric, the chem FET or floating gate FET has a loss of sensitivity over time. Dyadic sensor 100 overcomes these problems with conventional FETs and decreases effects of already adsorbed layers of analyte on analyte gate 4 by changing the top gate voltage in a presence of the adsorbed layers.

Additionally, dyadic sensor 100 selectively senses inter-molecular interactions in a composition that includes a plurality of analytes 58 and senses a selected analyte selectively, e.g., via adsorbant 110 disposed on analyte gate 4, wherein adsorbant 110 interact (e.g., bind) to a selected analyte with a selected specificity (e.g., high specificity, low specificity, and the like).

The articles and processes herein are illustrated further by the following Examples, which are non-limiting.

### EXAMPLES

### Example 1

### Fabrication of a Dyadic Sensor

A dyadic sensor was fabricated by first defining the control gate using photolithography, followed by depositing 20 nm of gate insulating material, A₂O₃, using an atomic layer deposition (ALD) process. Single crystal monolayer MoS2 was exfoliated onto the control gate insulator. This was followed by ebeam lithography to define and metallize source and drain contacts with 2 nm of Ti and 50 nm Au using e-beam deposition. Deposition of 20 nm of Al₂O₃ with ALD followed to define the analyte gate. Finally, an analyte gate contact extension was patterned with e-beam lithography and then metallized with 2 nm of Ti and 50 nm Au using e-beam deposition.

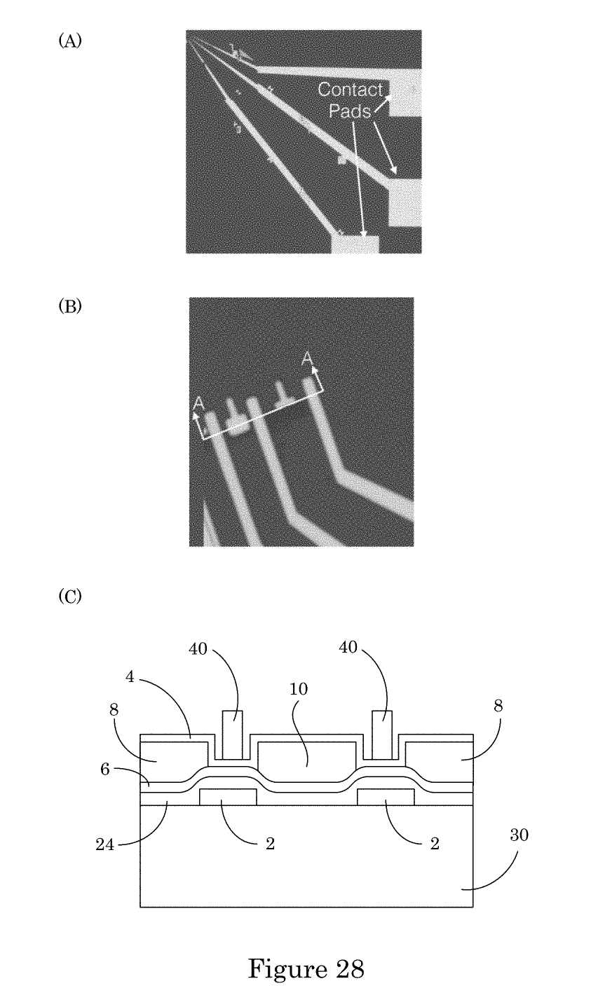

FIG. 28 shows the array of clichalcogenide asymmetric dyadic sensors in panel A. Panel B shows a zoomed view of a portion of the clichalcogenide asymmetric dyadic sensor shown in panel A. Here, arrays of dyadic sensors with varying lengths of two-dimensional active layers to vary sensitivity and drive current of the dyadic sensors in the array.

### Example 2

### Operation of a Dyadic Sensor

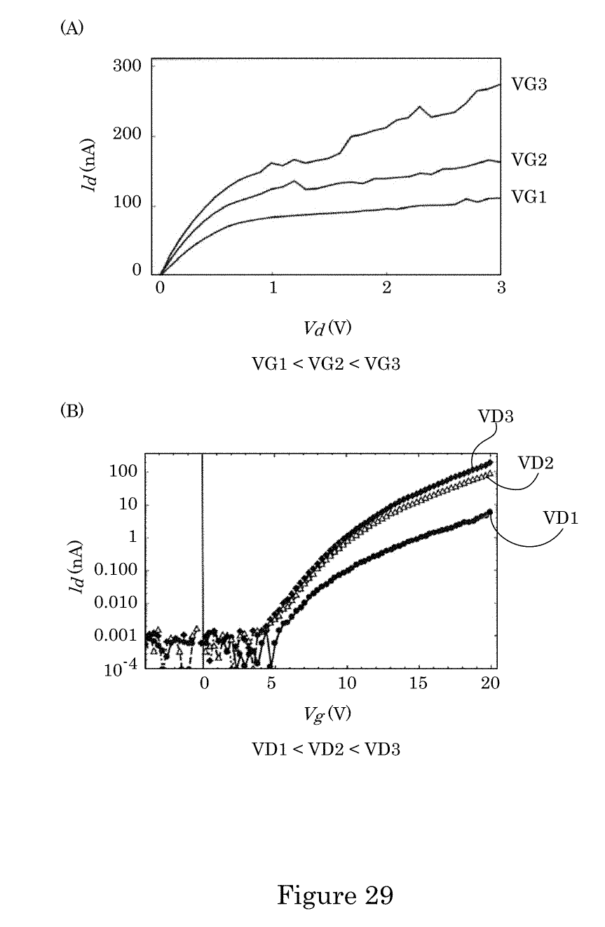

Dyadic sensors in the array described in Example 1 were operated by placing the devices in a probe station and probing the source, drain, and control gate contacts. I-V curves were measured using a semi-conductor parameter analyzer to sweep the drain voltage and step the gate voltage to obtain the plots in FIG. 29.

FIG. 29 shows data from the operation of the dyadic sensors. The drain current (I_{d}) was plotted against the drain voltage (V_{d}) for three independent gate potentials (V_{g}). V_{d} was varied from 0 to 3V and drain current I_{d} for each sweep was recorded. Here, transfer characteristics of the dyadic sensors were verified by plotting I_{d} against V_{g} for three independent values of V_{d}. The ratio of the saturation current (Iₒₙ) to the current when the dyadic sensors is off (I_{off}) was found to be greater than 10⁵.

### Example 3

### Detecting an Analyte with a Dyadic Sensor

Dyadic sensors in the array described in Example 1 were used to sense an analyte by placing a droplet with known analyte concentration directly in contact with the analyte gate contact. At the end of the measurement period, the analyte gate contact was rinsed with a buffer solution consisting of 1M NaCl and 30 mM of TRIS-EDTA at pH 7.2 to remove the analyte.

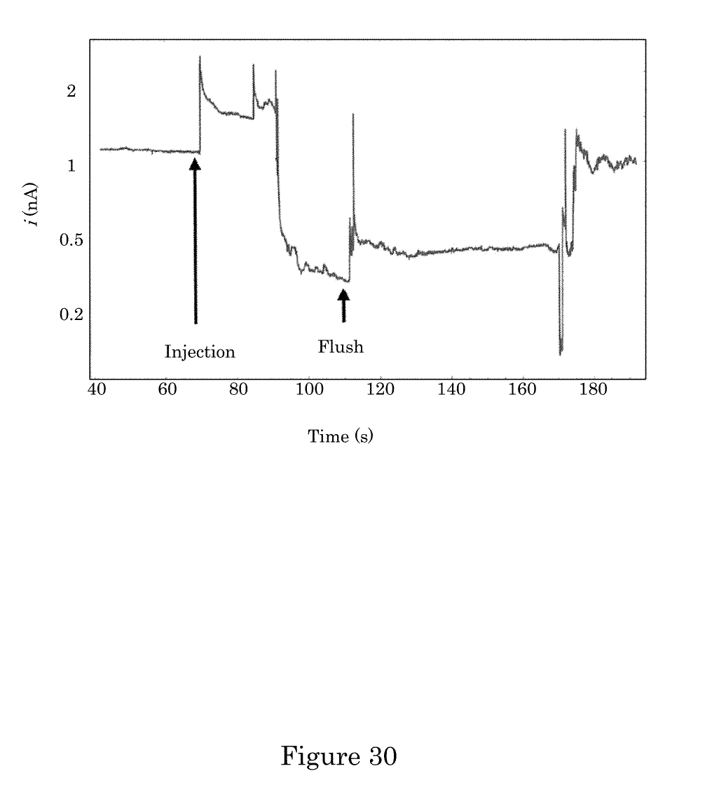

FIG. 30 shows drain current I_{d} as a function of time. 40 nano moles/L of single-stranded DNA (ssDNA) was injected onto the sensing surface at t=65 s. This resulted in a rapid change in the drain current from 1 nA to ˜0.2 nA commensurate with the adsorbed charge from the ssDNA molecules in solution. The ssDNA was subsequently flushed for several seconds starting at t=110 s. This resulted in I_{d}recovering to its baseline value of 1 nA.

### Example 4

### Functionalization of a Dyadic Sensor

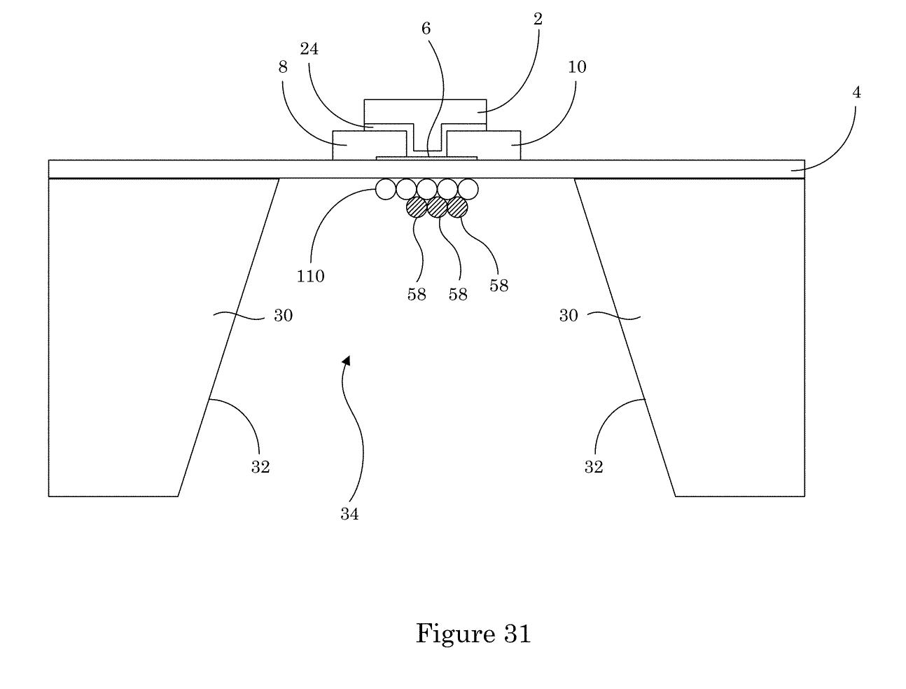

To one of the dyadic sensors in the array described in Example 1, a receptor protein was attached to the analyte gate as an adsorbant as shown in FIG. 31. The attachment of a receptor as an analyte to the receptor protein at the analyte gate provided a change in the drain current of the two-dimensional active layer. Further, the receptor binds various analytes (e.g., serotonin, a drug molecule, ligand, and the like). Interaction between adsorbant and the analyte can be an electrostatic interaction. Upon binding a ligand molecule as the analyte, the potential of the dyadic sensor is further modulated. A magnitude of change of drain current is proportional to the charge of the molecule, screening, or other environmental effect. This change modulates the amount of drain current, and the amount is proportional to the strength of the interaction. The change in drain current provides sensing, e.g., detection or electrostatic characterization, of the interaction between the analyte and the adsorbant. Removal of the ligand from the adsorbant returns the drain current to a previous value. A time evolution of the interaction was recorded by characterizing the rate at which interactions started and the rate at which interactions ended and provided kinetic characterization of the interaction and change in the interaction.

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

Reference throughout this specification to “one embodiment,” “particular embodiment,” “certain embodiment,” “an embodiment,” or the like means that a particular feature, structure, or characteristic described in connection with the embodiment is included in at least one embodiment. Thus, appearances of these phrases (e.g., “in one embodiment” or “in an embodiment”) throughout this specification are not necessarily all referring to the same embodiment, but may. Furthermore, particular features, structures, or characteristics may be combined in any suitable manner, as would be apparent to one of ordinary skill in the art from this disclosure, in one or more embodiments.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix “(s)” as used herein is intended to include both the singular and the plural of the term that it modifies, thereby including at least one of that term (e.g., the colorant(s) includes at least one colorants). “Optional” or “optionally” means that the subsequently described event or circumstance can or cannot occur, and that the description includes instances where the event occurs and instances where it does not. As used herein, “combination” is inclusive of blends, mixtures, alloys, reaction products, and the like.

As used herein, “a combination thereof” refers to a combination comprising at least one of the named constituents, components, compounds, or elements, optionally together with one or more of the same class of constituents, components, compounds, or elements.

All references are incorporated herein by reference.

The use of the terms “a” and “an” and “the” and similar referents in the context of describing the invention (especially in the context of the following claims) are to be construed to cover both the singular and the plural, unless otherwise indicated herein or clearly contradicted by context. “Or” means “and/or.” Further, the conjunction “or” is used to link objects of a list or alternatives and is not disjunctive; rather the elements can be used separately or can be combined together under appropriate circumstances. It should further be noted that the terms “first,” “second,” “primary,” “secondary,” and the like herein do not denote any order, quantity, or importance, but rather are used to distinguish one element from another. The modifier “about” used in connection with a quantity is inclusive of the stated value and has the meaning dictated by the context (e.g., it includes the degree of error associated with measurement of the particular quantity).

What is claimed is:

1. A dyadic sensor to sense an analyte, the dyadic sensor comprising:
an analyte gate;
a two-dimensional active layer disposed on the analyte gate and comprising a transition metal dichalcogenide, black phosphorous, graphene oxide, indium selenide, or silecene;
a source electrode disposed on the two-dimensional active layer and in electrical communication with the two-dimensional active layer;
a drain electrode disposed on the two-dimensional active layer and in electrical communication with the two-dimensional active layer and in electrical communication with the source electrode via the two-dimensional active layer; and
a control gate disposed on the two-dimensional active layer and controlling the communication of electrical current in the two-dimensional active layer between the source electrode and the drain electrode,
wherein the electrical current communicated in the two-dimensional active layer is changed in response to a change in an electrical charge present at the analyte gate due to the analyte.

2. The dyadic sensor of claim 1, further comprising a gate insulating layer interposed between the control gate and the two-dimensional active layer.

3. The dyadic sensor of claim 1, further comprising a substrate on which the analyte gate is disposed,
wherein the analyte gate is interposed between the substrate and the two-dimensional active layer.

4. The dyadic sensor of claim 1, further comprising an analyte gate contact disposed on the analyte gate,
wherein the analyte gate is interposed between the analyte gate contact and the two-dimensional active layer.

5. The dyadic sensor of claim 4, further comprising a substrate on which the analyte gate is disposed,
wherein the analyte gate is interposed between the substrate and the two-dimensional active layer.

6. The dyadic sensor of claim 5, further comprising an analyte gate extension disposed on the substrate and in electrical communication with the analyte gate contact.

7. The dyadic sensor of claim 6, further comprising a microfluidic chamber disposed on the substrate and comprising a flow channel,
wherein:
the flow channel provides for a flow of the analyte,
a portion of the analyte gate extension is exposed in the flow channel for contact with the analyte, and
the electrical charge present at the analyte gate changes due to contact of the analyte gate extension with the analyte.

8. The dyadic sensor of claim 7, wherein the microfluidic chamber further comprises a cover disposed on the substrate, and
the cover in combination with the substrate bounds the flow channel.

9. The dyadic sensor of claim 8, wherein the substrate comprises:
a first substrate on which the analyte gate and the analyte gate contact are disposed; and
a second substrate on which the microfluidic chamber is disposed.

10. The dyadic sensor of claim 9, wherein the first substrate and the second substrate are spaced apart, and
the analyte gate extension spans a separation between the first substrate and the second substrate.

11. The dyadic sensor of claim 1, wherein the two-dimensional active layer comprises the transition metal clichalcogenide, and the transition metal clichalcogenide comprises:
a transition metal; and
a chalcogen.

12. The dyadic sensor of claim 11, wherein the transition metal clichalcogenide further comprises a chemical formula MX₂,
wherein M comprises the transition metal, and X comprises a chalcogenide of the chalcogen.

13. The dyadic sensor of claim 11, wherein the transition metal clichalcogenide further comprises a chemical formula MₘM′₁₋ₘX₂,
wherein M and M′ are different transition metals, and
0<m<1.

14. The dyadic sensor of claim 11, wherein the transition metal clichalcogenide further comprises a chemical formula MXₓX′₂₋ₓ, where X and X′ are different chalcogenides, and 0<x<2,

15. The dyadic sensor of claim 11, wherein the transition metal dichalcogenide further comprises a chemical formula MₘM′₁₋ₘXₓX′₂₋ₓ, where M and M′ are different transition metals, X and X′ are different chalcogenides, 0<m<1, and 0<x<2.

16. A process for sensing an analyte, the process comprising:
providing the dyadic sensor of claim 1;
subjecting the source electrode and the drain electrode with a first potential difference comprising a drain voltage;
subjecting the control gate with a gate voltage; and
monitoring a drain current to sense a presence of the analyte at the analyte gate.

17. The process of claim 16, further comprising:
controlling a frequency of the gate voltage with a frequency driver,
wherein monitoring the drain current comprises detecting the drain current at the frequency of the gate voltage.

18. The process of claim 17, further comprising:
controlling an amplitude of the gate voltage with a control loop feedback controller.

19. The process of claim 18, further comprising:
providing an error signal from the frequency driver to the control loop feedback controller; and
providing a control signal from the control loop feedback controller to control the amplitude of the gate voltage,
wherein the control signal changes in response to a change in the error signal.

20. The process of claim 16, wherein the two-dimensional active layer comprises the transition metal dichalcogenide, and the transition metal dichalcogenide comprises a chemical formula MX₂,
M comprises a transition metal, and
X comprises a chalcogenide.
